(19) United States
(12) Patent Application Publication
(10) Pub. No.: US 2026/0223417 A1
(43) Pub. Date: Jul. 30, 2026

(54) Charge-Balanced Mesa for Semiconductor Device

(71) Applicant: Wolfspeed, Inc., Durham, NC (US)

(72) Inventor: Thomas Edgar Harrington, III, Carrollton, TX (US)

(21) Appl. No.: 19/040,345

(22) Filed: Jan. 29, 2025

(51) Int. Cl. H10D 62/00; H10D 12/00; H10D 12/01; H10D 30/01; H10D 30/66; H10D 62/60; H10D 62/81; H10D 62/832; H10D 64/23

(52) U.S. Cl. CPC H10D 62/054; H10D 12/038; H10D 12/481; H10D 30/0291; H10D 30/0297; H10D 30/66; H10D 30/668; H10D 62/60; H10D 62/812; H10D 62/8325; H10D 64/252; H10D 64/258

(57) ABSTRACT

An example semiconductor device includes a wide bandgap semiconductor structure having a first mesa and a second mesa. The example semiconductor device includes a dielectric between the first mesa and the second mesa. In some implementations, each of the first mesa and the second mesa includes a first doped column. The first doped column includes a plurality of first dopants of a first conductivity type. Each of the first mesa and the second mesa include two second doped columns. Each second doped column comprising a plurality of second dopants of a second conductivity type.

### FIELD

The present disclosure relates generally to semiconductor devices.

### BACKGROUND

Power semiconductor devices are used to carry large currents and support high voltages. A wide variety of power semiconductor devices are known in the art including, for example, power Metal Oxide Semiconductor Field Effect Transistors (“MOSFET”), bipolar junction transistors (“BJTs”), Insulated Gate Bipolar Transistors (“IGBT”), Schottky diodes, Junction Barrier Schottky (“JBS”) diodes, merged p-n Schottky (“MPS”) diodes, Gate Turn-Off Transistors (“GTO”), MOS-controlled thyristors and various other devices. These power semiconductor devices are generally fabricated from monocrystalline silicon semiconductor material, or, more recently, from silicon carbide or gallium nitride based semiconductor materials.

### SUMMARY

Aspects and advantages of embodiments of the present disclosure will be set forth in part in the following description, or can be learned from the description, or can be learned through practice of the embodiments.

In an aspect, the present disclosure provides an example semiconductor device. In some implementations, the example semiconductor device includes a wide bandgap semiconductor structure having a first mesa and a second mesa. In some implementations, the example semiconductor device includes a dielectric between the first mesa and the second mesa. In some implementations, each of the first mesa and the second mesa includes a first doped column, the first doped column comprising a plurality of first dopants of a first conductivity type, wherein each of the first mesa and the second mesa comprise two second doped columns, each second doped column comprising a plurality of second dopants of a second conductivity type.

In an aspect, the present disclosure provides an example method of fabricating a semiconductor device. In some implementations, the example method of fabricating a semiconductor device includes providing a wide bandgap semiconductor structure on a substrate. In some implementations, the example method of fabricating a semiconductor device includes providing one or more mesas in the wide bandgap semiconductor structure. In some implementations, the example method of fabricating a semiconductor device includes implanting dopants at a non-perpendicular implant angle into each of the one or more mesas.

In an aspect, the present disclosure provides an example semiconductor device. In some implementations, the example semiconductor device includes a substrate. In some implementations, the example semiconductor device includes a wide bandgap semiconductor structure, the semiconductor structure comprising a drift region and at least one mesa on the drift region. In some implementations, the example semiconductor device includes a first doped column in the mesa, the first doped column comprising dopants of a first conductivity type. In some implementations, the example semiconductor device includes two second doped columns in the mesa, the second doped columns comprising dopants of a second conductivity type. In some implementations, the example semiconductor device includes a gate structure on the mesa. In some implementations, the first doped column is between the two second doped columns, wherein the first doped column and the two second doped column provide a charge-balanced structure.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts a cross-sectional view of example unit cells of an example power silicon carbide-based semiconductor device according to example aspects of the present disclosure.

FIG. 2 depicts a cross-sectional view of example unit cells of an example planar gate power semiconductor device according to example aspects of the present disclosure.

FIG. 3 depicts a cross-sectional view of example unit cells of an example power semiconductor device according to example aspects of the present disclosure.

FIG. 4 depicts a cross-sectional view of example unit cells of an example power semiconductor device according to example aspects of the present disclosure.

FIG. 5 depicts a cross-sectional view of two example unit cells of an example power semiconductor device according to example aspects of the present disclosure.

FIG. 6 depicts a flowchart diagram of an example method according to example aspects of the present disclosure.

FIGS. 7-13 depict an example method according to example aspects of the present disclosure.

Repeat use of reference characters in the present specification and drawings is intended to represent the same and/or analogous features or elements of the present invention.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

A power semiconductor device may have a semiconductor substrate, such as a silicon carbide substrate having a first conductivity type (e.g., an n-type substrate), on which an epitaxial layer structure having the first conductivity type (e.g., n-type) is formed. A portion of this epitaxial layer structure (which may include one or more separate layers) functions as a drift region of the power semiconductor device. The device typically includes an “active region,” which includes one or more power semiconductor devices that have a junction such as a p-n junction. The active region may be formed on and/or in the drift region. The active region acts as a main junction for blocking voltage in the reverse bias direction and providing current flow in the forward bias direction. The power semiconductor devices may have a unit cell structure in which the active region of each power semiconductor device includes a plurality of individual “unit cell” devices that are electrically connected in parallel and that together function as a single power semiconductor device.

Power semiconductor devices are often fabricated from wide bandgap semiconductor materials, such as silicon carbide or Group III-nitride based semiconductor materials (e.g., gallium nitride). Herein, a wide bandgap semiconductor material refers to a semiconductor material having a bandgap greater than 1.40 eV. Aspects of the present disclosure are discussed with reference to silicon carbide-based semiconductor structures as wide bandgap semiconductor structures. Those of ordinary skill in the art, using the disclosures provided herein, will understand that the power semiconductor devices according to example embodiments of the present disclosure may be used with any semiconductor material, such as other wide bandgap semiconductor materials, without deviating from the scope of the present disclosure. Example wide bandgap semiconductor materials include silicon carbide (e.g., 2.996 eV band gap for alpha silicon carbide at room temperature) and the Group III-nitrides (e.g., 3.36 eV band gap for gallium nitride at room temperature).

Power semiconductor devices can have a lateral structure or a vertical structure. In a device having a lateral structure, the terminals of the device (e.g., the drain, gate and source terminals for a power MOSFET device) are on the same major surface (e.g., top surface or bottom surface) of a semiconductor structure. In contrast, in a power semiconductor device having a vertical structure, at least one terminal is provided on each major surface of the semiconductor structure. For instance, in a vertical MOSFET device, the source may be on the top surface of the semiconductor structure and the drain may be on the bottom surface of the semiconductor structure. Herein, the term “semiconductor structure” refers to a structure that includes one or more semiconductor layers, such as semiconductor substrates and/or semiconductor epitaxial layers.

Vertical power semiconductor devices, including a MOSFET transistor or an IGBT transistor, can have a standard gate electrode design in which the gate electrode of the transistor is formed on top of the semiconductor structure (e.g., a planar gate electrode design). Alternatively, the power semiconductor devices may have the gate electrode in a gate trench within the semiconductor structure. Power semiconductor devices having trench gate electrodes are typically referred to as trench gate devices (e.g., trench gate MOSFETs or trench gate IGBTs). With the standard gate electrode design, the channel region of each unit cell transistor is horizontally disposed underneath the gate electrode. In contrast, in the trench gate design, the channel is vertically disposed. Trench gate devices may provide enhanced performance but may require a more complicated manufacturing process(s).

In vertical power semiconductor devices, the blocking voltage rating of the device is typically determined by the thickness and the doping concentration of the drift region. In particular, to increase the breakdown voltage of the device, the doping concentration of the drift region is decreased and/or the thickness of the drift region is increased. Typically, during the design phase, a desired blocking voltage rating is selected, and then the thickness and doping of the drift region are chosen based on the desired blocking voltage rating. Since the drift region is the current path for the device in the forward “on” state, the decreased doping concentration and increased thickness of the drift region may result in a higher on-state resistance for the device. Thus, there is an inherent tradeoff between the on-state resistance and blocking voltage for these devices.

Superjunction-type drift regions have been introduced in which the drift region is divided into alternating, side-by-side heavily-doped n-type and p-type regions. In vertical semiconductor devices, these side-by-side n-type and p-type regions are often referred to as doped columns. The doped columns may have fin shapes, column shapes or other shapes. The thickness and doping of these doped columns may be controlled so that the superjunction will act like a p-n junction with low resistance and a high breakdown voltage. Thus, by using superjunction structures, the conventional tradeoff between the breakdown voltage of the device and the doping level of the drift region may be avoided. Typically, at least some of the doped columns are formed via ion implantation, and so-called “deep” implantation is used (e.g., ion implantation depths of 2.5 microns to 5 microns or more) to enhance the effect of the superjunction structure. In superjunction devices, the doping concentration in the drift region may be increased in order to reduce the on-state resistance of the device with reduced effect on the breakdown voltage.

Example aspects of the present disclosure are directed to charge-balanced semiconductor devices, such as superjunction semiconductor devices. In some examples, charge-balanced superjunction devices may have doped columns that form a charged-balanced structure. A charged-balanced structure will have a substantially equal number of dopants (e.g., within 10% of equal) of a first conductivity type (e.g., n-type dopants) and dopants of a second conductivity type (e.g., p-type dopants) in separate doped regions of the structure. For instance, a charged-balanced structure may have a first doped region (e.g., a first doped column) of a first conductivity type between two second doped regions (e.g., second doped columns) of a second conductivity type. The dopant concentration of the first doped region may be substantially equal to the total dopant concentration of the two second doped regions to provide a charge-balanced structure.

In most charge-balanced device implementations, it is very difficult to achieve charge balance in high volume manufacturing. This may be due to charge discrepancies resulting from non-uniform dopant concentration in the p-type and n-type regions of the p-n junction. Dopant concentrations may be determined by introducing one or more dopants during an epitaxial deposition process or by introducing one or more dopants in an ion-based implantation process performed. An ion-based implantation process may rely on masking (e.g., a photoresist mask or a hard mask) to achieve the desired dopant region and/or concentration in the device. Both of these techniques (e.g., epitaxial deposition including dopants or ion-implantation of dopants) are limited in their ability to provide the level of precision required to achieve equal doping in the alternating, side-by-side heavily-doped n-type and p-type regions of the device required for charge balance. For instance, doping uniformity (e.g., a concentration of dopants across a region) incorporated in a superjunction semiconductor device during an epitaxial deposition process is limited by the consistency of dopant delivery to the epitaxial film, which may be interrelated with one or more of a process temperature, pressure, position on a workpiece (e.g., a central portion vs. an edge portion) or other variables. Doping uniformity (e.g., a concentration of dopants across a region) incorporated in a superjunction semiconductor device during an ion-based implantation process may be limited by the variation in a critical dimension of the one or more mask openings. Taken together, these two problems make it difficult to achieve high yields for superjunction devices without compromising with a larger gate pitch and/or lower doping levels, both of which may increase drain-source on-resistance (e.g., RdsOn) resulting in higher power loss of a semiconductor device and lessened device performance.

According to examples of the present disclosure, limitations of superjunction semiconductor device fabrication may be overcome to achieve scalable manufacturing of high-performance semiconductor devices by etching mesas into the surface of the semiconductor workpiece and implanting both dopant types (e.g., p-type and n-type) at a non-perpendicular implant angle into at least a portion of the mesa to form the alternating, side-by-side heavily-doped n-type and p-type regions. The ion-based implantation process performed at a non-perpendicular implant angle may lead to higher precision and highly effective doping concentrations (e.g., charge balance) in a superjunction semiconductor device. Charge balance is therefore achieved in this manner without relying on critical dimension control in a lithographic masking process or a precise level of initial dopant concentration that may be included in the semiconductor workpiece (e.g., dopant concentration in an epitaxial layer or other structure) from which the mesas may be formed.

Accordingly, aspects of the present disclosure are directed to a semiconductor device. The semiconductor device includes a wide bandgap semiconductor structure having a first mesa and a second mesa. The semiconductor device includes a dielectric (e.g., an insulator layer) between the first mesa and the second mesa. Each of the first mesa and the second mesa includes a first doped column. The first doped column includes a plurality of first dopants of a first conductivity type. Each of the first mesa and the second mesa include one or more second doped columns. In some examples, the first doped column may be between the two second doped columns. The second doped column(s) may include a plurality of second dopants of a second conductivity type. In some embodiments, the plurality of first dopants and the plurality of second dopants are such that each of the first mesa and the second mesa is a charge-balanced structure.

In some embodiments, each of the first mesa and the second mesa is on a common drift region. In some embodiments, the wide bandgap semiconductor structure is on a substrate. In some embodiments, the wide bandgap semiconductor structure on a substrate includes a drain electrode on the substrate.

In some embodiments, each of the first mesa and the second mesa includes a JFET region. In some embodiments, the JFET region is at least partially vertically aligned with the first doped column. In some embodiments, each of the first mesa and the second mesa comprises a well region. In some embodiments, the second doped column for each of the first and second mesa extends from the well region to a drift region.

In some embodiments, the semiconductor device includes a planar gate structure on each of the first mesa and the second mesa. In some embodiments, the semiconductor device includes a trench gate structure in each of the first mesa and the second mesa.

In some embodiments, each of the first mesa and the second mesa have a height in a range of about 1 micron to about 5 microns. In some embodiments, the dielectric includes silicon dioxide. In some embodiments, the dielectric includes a silicate glass. In some embodiments, the wide bandgap semiconductor structure includes silicon carbide. In some embodiments, the semiconductor device is a MOSFET. In some embodiments, the semiconductor device is an IGBT.

Another example aspect of the present disclosure is directed toward a method of fabricating a semiconductor device. The method includes providing a wide bandgap semiconductor structure on a substrate. The method includes providing one or more mesas in the wide bandgap semiconductor structure (e.g., etching trenches to provide one or more mesas). The method includes implanting dopants at a non-perpendicular implant angle into each of the one or more mesas.

In some embodiments, the non-perpendicular implant angle is in a range of about 10 degrees to about 80 degrees from a horizontal axis, such as about 15 degrees to about 75 degrees, such as about 30 degrees to about 60 degrees. In some embodiments, implanting dopants at a non-perpendicular implant angle into each of the one or more mesas further includes implanting first dopants of a first conductivity type to form a first doped column in each of the one or more mesas. Implanting dopants at a non-perpendicular implant angle into each of the one or more mesas further includes implanting second dopants of a second conductivity type to form a second doped column in each of the one or more mesas. In some embodiments, the non-perpendicular implant angle is based at least in part on a height of the one or more mesas. In some embodiments, the non-perpendicular implant angle is based at least in part on a width between the one or more mesas.

In some embodiments, implanting first dopants is associated with a first implant energy and a first implant dosage and implanting second dopants is associated with a second implant energy and a second implant dosage. In some embodiments, the first implant energy is different than the second implant energy. In some embodiments, implanting first dopants is associated with a first non-perpendicular implant angle and implanting second dopants is associated with a second non-perpendicular implant angle relative to a vertical component of the mesa. In some embodiments, the first non-perpendicular implant angle is different than the second non-perpendicular implant angle. In some embodiments, the first non-perpendicular implant angle is larger than the second non-perpendicular implant angle. In some embodiments, the second non-perpendicular implant angle is larger than the first non-perpendicular implant angle. In some embodiments, the first implant dosage and the second implant dosage is such that each of the one or more mesas is a charge-balanced structure.

In some embodiments, the method further includes providing a surface doped region in the one or more mesas in an ion-based implantation process. In some embodiments, the surface doped region includes one or more of a source region, a well region, a contact region, and/or a JFET region.

In some embodiments, implanting dopants at the non-perpendicular implant angle into each of the one or more mesas further includes implanting dopants at the non-perpendicular implant angle from a first direction and implanting dopants at the non-perpendicular implant angle from a second direction. The first direction is different than the second direction and the non-perpendicular implant angle is mirrored with respect to a vertical component of the mesa.

In some embodiments, the method includes providing a passivation layer on the semiconductor structure prior to implanting dopants at a non-perpendicular implant angle. In some embodiments, the method includes providing a mask layer on the one or more mesas prior to implanting dopants at a non-perpendicular implant angle. In some embodiments, the method includes providing an insulating layer adjacent the one or more mesas after implanting dopants at a non-perpendicular implant angle. In some embodiments, the insulating layer includes a dielectric such as silicon dioxide. In some embodiments, the dielectric includes a silicate glass. In some embodiments, each of the one or more mesas has a height in a range of about 1 micron to about 5 microns. In some embodiments, the wide bandgap semiconductor structure includes silicon carbide. In some embodiments, the semiconductor device is a MOSFET. In some embodiments, the semiconductor device is an IGBT.

Aspects of the present disclosure provide a number of technical effects and benefits. For instance, implanting both dopant types (e.g., p-type and n-type) at a non-perpendicular implant angle into at least a portion of the mesa may lead to scalable manufacturing of high-performance semiconductor devices. Dopant uniformity may be improved relative to an ion-based implantation process performed at a perpendicular angle relative to the substrate of the semiconductor device. Charge balance of the doped regions of the mesa may be better controlled through the ion-based implantation process performed at a non-perpendicular angle through dopant uniformity. The impacts of process constraints may be lessened. For example, variation of the critical dimension of mask openings may not impact ion-based implantation processes performed at a non-perpendicular implant angle relative to other implant processes. Further, the dopant concentration of an epitaxial layer from which the mesas may be formed may not impact the charge balance of the semiconductor device. Performance of a superjunction semiconductor device may be improved, without acquiescing to a wider gate pitch, power loss of the device, lower breakdown voltage, or reducing doping concentrations.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region, or substrate is referred to as being “on” or extending “onto” another element, it may be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

Aspects of the specification are discussed with reference to dopants of the first conductivity type as n-type dopants and dopants of the second conductivity type as p-type dopants for purposes of illustration and discussion. The claims may refer to dopants of a first conductivity type and dopants of a second conductivity type. This is intended to claim that the dopants of the first conductivity type are different from dopants of the second conductivity type. For instance, dopants of the first conductivity type can be n-type dopants and dopants of the second conductivity type can be p-type dopants. In addition, dopants of the first conductivity type can be p-type dopants and dopants of the second conductivity type can be n-type dopants and still be within the scope of the claims.

Aspects of the present disclosure are discussed with reference to silicon carbide-based transistor and diode devices for purposes of illustration and discussion. Those of ordinary skill in the art, using the disclosures provided herein, will appreciate that certain aspects of the present disclosure may be applicable to other transistor or diode devices without deviating from the scope of the present disclosure.

In the drawings and specification, there have been disclosed typical embodiments and, although specific terms are employed, they are used in a generic and descriptive sense only and not for purposes of limitation of the scope set forth in the following claims.

Aspects of the present disclosure are discussed with reference to silicon carbide-based semiconductor structures, such as silicon carbide-based MOSFETs. Those of ordinary skill in the art, using the disclosures provided herein, will understand that the power semiconductor formation processes or devices according to example embodiments of the present disclosure, may be used with any semiconductor material, such as other wide band gap semiconductor materials and other non-compound semiconductor materials such as silicon, without deviating from the scope of the present disclosure. Example wide band gap semiconductor materials include silicon carbide (e.g., 2.996 eV band gap for alpha silicon carbide at room temperature) and the Group III-nitrides (e.g., 3.36 eV band gap for gallium nitride at room temperature).

In the drawings and specification, there have been disclosed typical embodiments and, although specific terms are employed, they are used in a generic and descriptive sense only and not for purposes of limitation of the scope set forth in the following claims.

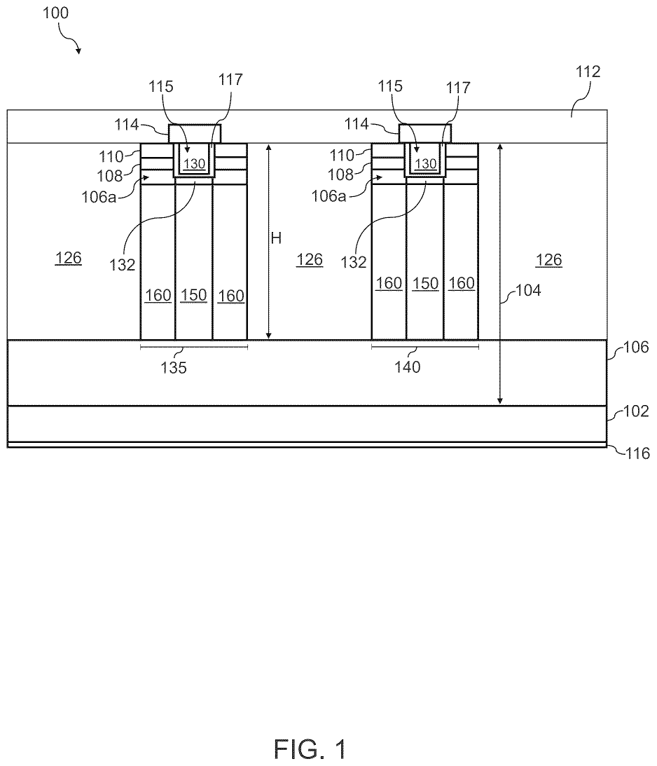

FIG. 1 is a cross-sectional view of two unit cells of an example power silicon carbide-based semiconductor device 100. The power semiconductor device 100 of FIG. 1 is a silicon carbide-based trench gate MOSFET. FIG. 1 is intended to represent structures for identification and description and is not intended to represent the structures to physical scale.

The power semiconductor device 100 includes a silicon carbide substrate 102. The power semiconductor device 100 includes a silicon carbide-based semiconductor structure 104 (e.g., epitaxial semiconductor structure) on the silicon carbide substrate 102. The substrate 102 may include, for example, a single crystal 4H silicon carbide semiconductor substrate. The substrate 102 may be heavily doped with n-type dopants (e.g., an n+ silicon carbide substrate). The dopants may comprise, for example, nitrogen or phosphorus or other suitable dopants. The substrate 102 may be any appropriate thickness (e.g., in a range of about 50 microns to about 500 microns, such as about 100 microns to about 360 microns, such as about 200 microns to about 300 microns, but thinner or thicker substrates are possible). Other substrates may be used without deviating from the scope of the present disclosure. The silicon carbide-based semiconductor structure 104 may be epitaxially formed on the substrate 102, for example by chemical vapor deposition (CVD) or other suitable growth techniques. Dopant implantation processes may be used to form doped regions in the semiconductor structure 104 (e.g., n-type regions, p-type regions) as described below.

The silicon carbide-based semiconductor structure 104 may include a doped (e.g., n-doped) silicon carbide drift region 106 on the substrate 102. The silicon carbide drift region 106 may be formed on the substrate 102 by epitaxial growth, for example, by CVD. The drift region 106 of FIG. 1 may have a uniform or nearly uniform dopant concentration across a thickness of the drift region 106. For instance, the drift region 106 may have a uniform or nearly uniform dopant concentration of dopants of a first conductivity type (such that the drift region is an n-type region). However, in other embodiments, the drift region 106 may have a non-uniform dopant concentration, such as a gradient dopant concentration that increases and/or decreases through a thickness of the drift region 106.

The dopant concentration of the drift region 106 may be, for instance, in a range of about 1×10¹⁴/cm³ to about 1×10¹⁷/cm³, such as about 1×10¹⁵/cm³ to about 2×10¹⁶/cm³, such as about 5×10¹⁵/cm³ to about 1×10¹⁶. The dopants may be, for example, nitrogen dopants or phosphorous dopants or any other suitable dopants. The drift region 106 may have a thickness in a range of about 1 micron to about 100 microns, such as about 3 microns to about 100 microns, such as about 6 microns to about 100 microns, such as about 3 microns to about 50 microns, such as about 3 microns to about 20 microns, such as about 4 microns to about 15 microns, such as about 4 microns to about 10 microns.

According to aspects of the present disclosure, the wide bandgap semiconductor structure 104 may include one or more mesas, such as a first mesa 135 and a second mesa 140. The first doped column 150 may be between the two second doped columns 160. Each of the first mesa 135 and the second mesa 140 may be included on a common drift region 106. More particularly, the first mesa 135 and the second mesa 140 may be on the drift region 106. Each of the first mesa 135 and the second mesa 140 may have a height H. The height H of the first mesa 135 and the second mesa 140 may be, for instance, in a range of about 0.5 microns to about 7 microns, such as about 1 micron to about 5 microns, such as about 2 microns to about 4 microns.

The first mesa 135 and the second mesa 140 may include a first doped column 150 of a second conductivity type (e.g., a plurality of p-type dopants, such as aluminum, boron, gallium, indium, or other suitable dopants). The first mesa 135 and the second mesa 140 may include one or more second doped columns 160 of a first conductivity type (e.g., a plurality of n-type dopants), such as two second doped columns 160 of the first conductivity type. The dopants of the first conductivity type may be, for instance, such as nitrogen, phosphorous, or other suitable dopants. The first doped column 150 may be between the second doped columns 160.

In the trench gate MOSFET semiconductor device 100 of FIG. 1, the doped column in the center of the first mesa 135 and the second mesa 140 has p-type dopants. The doped columns at the sides of the first mesa 135 and the second mesa 140 has n-type dopants. For sake of consistency, the p-type dopants are labelled second conductivity type and the n-type dopants are labeled first conductivity type. For purposes of the claims, the p-type dopants may be considered dopants of a first conductivity type and n-type dopants may be considered dopants of a second conductivity type without deviating from the scope of the present disclosure.

In some embodiments, the plurality of first dopants and the plurality of second dopants are such that each of the first mesa 135 and the second mesa 140 is a charge-balanced structure. A charged-balanced structure will have a substantially equal number of dopants (e.g., within 10% of equal) of a first conductivity type (e.g., n-type dopants) and dopants of a second conductivity type (e.g., p-type dopants) in separate doped regions of the structure. For instance, the dopant concentration of the first doped column 150 may be substantially equal to the total combined dopant concentration of the two second doped columns 160 to provide a charge-balanced structure. The example semiconductor device 100 of FIG. 1 is a superjunction trench gate MOSFET. The semiconductor device 100 has doped surface regions in each of the first mesa 135 and the second mesa 140 to form the superjunction trench gate MOSFET. For instance, each of the first mesa 135 and the second mesa 140 may include a p-type well region 108. The p-type well region 108 may provide p-wells for the power semiconductor device 100. The p-type well region 108 may be formed, for instance, by epitaxial growth followed by implantation of p-type dopants. The p-type well regions 108 may be moderately doped with p-type dopants (e.g., aluminum, boron, gallium, indium) at concentrations in a range of about 1×10¹⁶/cm³ to about 1×10¹⁸/cm³, such about 5×10¹⁶/cm³ to about 2×10¹⁷/cm³, such as about 5×10¹⁶/cm³ to about 1×10¹⁷/cm³. In some embodiments, the concentration of dopants in the p-type well regions 108 may be higher than the concentration of dopants in the drift region 106.

An n-type source region 110 may be on the well region 108. The source region 110 may be heavily doped with an n-type doping material (n+) at a dopant concentration, for instance, in a range of about 1×10¹⁸/cm³ to about 5×10²¹/cm³, such as about 1×10¹⁹/cm³ to about 1×10²¹/cm³, such as about 5×10¹⁹/cm³ to about 5×10²⁰/cm³. The heavily doped n-type source region 110 may be formed by epitaxial growth followed by ion implantation of n-type dopants (e.g., nitrogen, phosphorus). In some embodiments, however, the n-type source region 110 may be formed by epitaxial growth.

The silicon carbide-based semiconductor structure 104 may include one or more p-type contact regions (not illustrated) adjacent the n-type source region 110. The p-type contact regions may be more heavily doped with p-type dopants than the p-type well regions 108. The p-type contact regions may be formed, for instance, by implantation of p-type dopants into the semiconductor structure 104. The p-type contact regions may be heavily doped with a p-type doping material at concentrations in a range of about 1×10¹⁹/cm³ to 1×10²¹ cm³, such as about 5×10¹⁹/cm³ to 5×10²⁰ cm³, such as about 5×10¹⁹/cm³ to 1×10²⁰ cm³. Each p-type contact region may be laterally adjacent one or more source regions 110 and may extend between a top surface of the semiconductor structure 104.

The semiconductor device includes a gate trench 115 in the silicon carbide-based semiconductor structure 104. The gate trench 115 extends through the source region 110, the well region 108 and onto the drift region 106. A gate dielectric layer 117 may be along a bottom surface and sidewalls of the gate trench 115. The gate dielectric layer 117 may be, for example, an oxide layer, and may include one or more layers. In some examples, the gate dielectric layer 117 includes one or more of SiO₂, SiN, Al₂O₃, MgOₓ, MgNₓ, ZnO, SiNₓ, SiOₓ, HfOₓ or other suitable dielectric layer. The gate dielectric layer 117 may insulate a gate structure 130 from the semiconductor structure 104.

A gate structure 130 may be in the gate trench 115. The gate structure 130 may comprise a metal and/or doped polysilicon on the gate dielectric layer 117 (e.g., gate oxide). In some examples, the gate structure 130 may be part of a continuous gate pattern including one or more gate buses, gate pads, etc. The gate structure 130, in some embodiments, may partially fill the gate trench 115 (so that the upper surface of the gate structure 130 is below an upper surface of the gate trench 115), may fill the gate trench 115, or may fill the gate trench and extend onto portions of the semiconductor structure 104 that are on either side of the gate trench 115.

In some examples, the semiconductor structure 104 may include a p-type trench shield region 132 in the semiconductor structure 104. The trench shield region 132 may be moderately or heavily doped with a p-type doping material (p+) at concentrations in a range of about 1×10¹⁷/cm³ to about 1×10²⁰/cm³, such as about 5×10¹⁷/cm³ to about 5×10¹⁹/cm³, such as about 1×10¹⁸/cm³ to about 1×10¹⁹/cm³. The trench shield region 132 may be beneath the gate trench 115 and may act to reduce electric field levels formed in the gate dielectric 117 during operation of the trench gate MOSFET device 100. In some embodiments, the semiconductor device 100 does not include a trench shield region 132.

A source electrode 112 may be on the n-type source regions 110. The source electrode 112 may provide an ohmic contact with the semiconductor structure 104. The source electrode 112 may include, for example, one or more metals such as nickel, titanium, tantalum, tungsten, aluminum or copper, or alloys or layered stacks of these along with appropriate barrier metals such as tantalum nitride, titanium nitride, titanium tungsten and others, or other suitable materials. In some embodiments, the source electrode 112 may include a separate ohmic contact layer (not shown), for instance, made of nickel silicide that may be formed by depositing a nickel layer which may be annealed into the silicon carbide semiconductor structure 104 to form the nickel silicide ohmic contact.

An insulating portion 114 may electrically insulate the source electrode 112 from the gate structure 130. The insulating portion 114 can be an interlayer dielectric and can include any suitable dielectric material.

A drain electrode 116 may be on the lower surface of the substrate 102. The drain electrode 116 may include, for example, similar materials to the source electrode 112, as this forms an ohmic contact to the substrate 102. The drain electrode 116 may include, for example, metals such as nickel, titanium, tungsten, silver, palladium, gold, aluminum or copper, or alloys or layered stacks of these or other suitable materials.

The semiconductor structure 104 may include a channel region and a JFET region 106a. The channel region may be the portion of the p-well region 108 that is adjacent to the gate trench 115. In some embodiments, the JFET region 106a may have a dopant concentration of dopants of the first conductivity type (e.g., n-type dopants) that may be greater than a dopant concentration of the remainder of the drift region 106. The JFET region 106a may have a portion that begins above the bottom of the gate trench 115 and extends to a depth in the first mesa 135 and the second mesa 140.

When a sufficient bias voltage is applied to the gate structure 130 in the gate trench 115, electrons will flow from the source electrode 190 to the drain electrode 192 through the channel region and JFET region 106a through the n-type second doped columns of the second conductivity type into the drift region 106. More specifically, the electrons flow from the source electrode 112, through the channel and then into the JFET region 106a through the second doped columns 160 and drift region 106 on their path to the drain electrode 116.

In some embodiments, the one or more second doped columns 160 of the first conductivity type (e.g., n-type) extends from the JFET region 106a to the drift region 106 such that the JFET region 106a at least partially overlaps the second doped columns 160. The gate trench 115 may at least partially overlap the first doped column 150.

As described below, the first doped column 150 may be a non-perpendicular implant defined first doped column formed by implanting dopants at a non-perpendicular angle into the first mesa 135 and the second mesa 140. The second doped columns 160 may be non-perpendicular implant defined second doped column formed by implanting dopants at a non-perpendicular angle into the first mesa 135 and the second mesa 140.

According to examples of the present disclosure, the semiconductor device 100 may further include an insulator layer 126 (e.g., a dielectric) between the first mesa 135 and the second mesa 140. The insulator layer 126 may be provided on the drift region 106 adjacent to at least one of the first mesa 135 and the second mesa 140 (e.g., in a trench between the first mesa 135 and the second mesa 140). The insulator layer 126 may have a surface that is coplanar with a surface (e.g., a top surface) of the wide bandgap semiconductor structure 104. In some examples, the insulator layer 126 may be an oxide, such as silicon dioxide. In some examples, the insulator layer 126 is a silicate glass. For instance, the insulator layer 126 may include a borosilicate glass and/or a borophosphosilicate glass (BPSG). Other suitable dielectric or insulating material(s) may be used as the insulator layer 126 without deviating from the scope of the present disclosure. The insulator layer 126 may electrically insulate the first mesa 135 and the second mesa 140.

While the semiconductor device 100 is illustrated and described as an n-type device, aspects of the present disclosure are similarly applicable to p-type devices, where the n-type layers described above are p-type layers and the p-type layers described above are n-type layers.

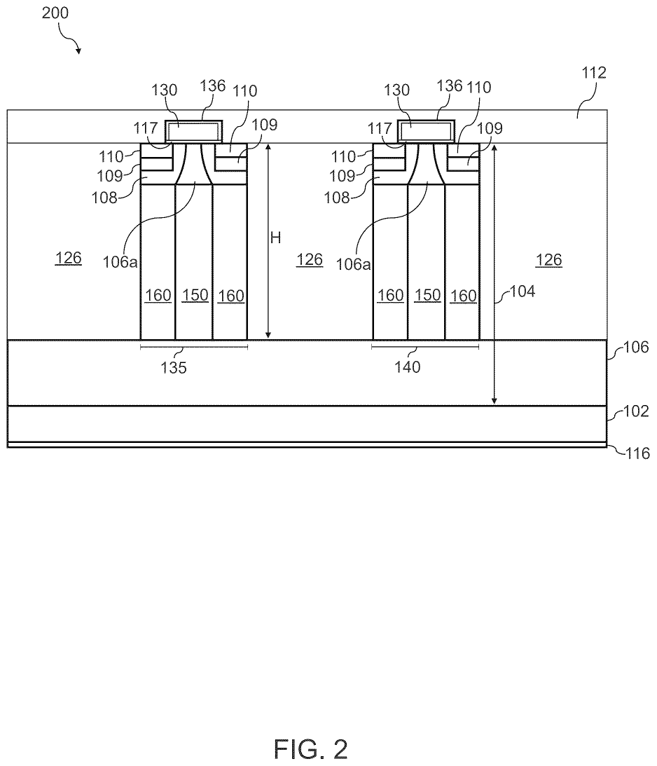

FIG. 2 depicts a cross-sectional view of example unit cells of an example planar gate superjunction MOSFET power semiconductor device 200 according to example embodiments of the present disclosure. The power semiconductor device 200 of FIG. 2 is a silicon carbide-based planar gate superjunction MOSFET. FIG. 2 is intended to represent structures for identification and description and is not intended to represent the structures to physical scale.

The semiconductor device 200 includes many of the same structures and regions as the semiconductor MOSFET 100 of FIG. 1. For instance, the power semiconductor device 200 includes a silicon carbide substrate 102. The power semiconductor device 200 includes a silicon carbide-based semiconductor structure 104 (e.g., epitaxial semiconductor structure) on the silicon carbide substrate 102. The substrate 102 may include, for example, a single crystal 4H silicon carbide semiconductor substrate. The substrate 102 may be heavily doped with n-type dopants (e.g., an n+ silicon carbide substrate). The dopants may comprise, for example, nitrogen or phosphorus or other suitable dopants. The substrate 102 may be any appropriate thickness (e.g., in a range of about 50 microns to about 500 microns, such as about 100 microns to about 360 microns, such as about 200 microns to about 300 microns, but thinner or thicker substrates are possible). Other substrates may be used without deviating from the scope of the present disclosure. The silicon carbide-based semiconductor structure 104 may be epitaxially formed on the substrate 102, for example by chemical vapor deposition (CVD) or other suitable growth techniques. Dopant implantation processes may be used to form doped regions in the semiconductor structure 104 (e.g., n-type regions, p-type regions) as described below.

The silicon carbide-based semiconductor structure 104 may include a doped (e.g., n-doped) silicon carbide drift region 106 on the substrate 102. The silicon carbide drift region 106 may be formed on the substrate 102 by epitaxial growth, for example, by CVD. The drift region 106 of FIG. 2 may have a uniform or nearly uniform dopant concentration across a thickness of the drift region 106. For instance, the drift region 106 may have a uniform or nearly uniform dopant concentration of dopants of a first conductivity type (such that the drift region is an n-type region). However, in other embodiments, the drift region 106 may have a non-uniform dopant concentration, such as a gradient dopant concentration that increases and/or decreases through a thickness of the drift region 106.

The dopant concentration of the drift region 106 may be, for instance, in a range of about 1×10¹⁴/cm³ to about 1×10¹⁷/cm³, such as about 1×10¹⁵/cm³ to about 2×10¹⁶/cm³, such as about 5×10¹⁵/cm³ to about 1×10¹⁶. The dopants may be, for example, nitrogen dopants or phosphorous dopants or any other suitable dopants. The drift region 106 may have a thickness in a range of about 1 micron to about 100 microns, such as about 3 microns to about 100 microns, such as about 6 microns to about 100 microns, such as about 3 microns to about 50 microns, such as about 3 microns to about 20 microns, such as about 4 microns to about 15 microns, such as about 4 microns to about 10 microns.

According to aspects of the present disclosure, the wide bandgap semiconductor structure 104 may include one or more mesas, such as a first mesa 135 and a second mesa 140. The first doped column 150 may be between the two second doped columns 160. Each of the first mesa 135 and the second mesa 140 may be included on a common drift region 106. More particularly, the first mesa 135 and the second mesa 140 may be on the drift region 106. Each of the first mesa 135 and the second mesa 140 may have a height H. The height H of the first mesa 135 and the second mesa 140 may be, for instance, in a range of about 0.5 microns to about 7 microns, such as about 1 micron to about 5 microns, such as about 2 microns to about 4 microns.

The first mesa 135 and the second mesa 140 may include a first doped column 150 of a first conductivity type (e.g., a plurality of n-type dopants, such as nitrogen, phosphorus, or other suitable dopants). The first mesa 135 and the second mesa 140 may include one or more second doped columns 160 of a second conductivity type (e.g., a plurality of p-type dopants), such as two second doped columns 160 of the first conductivity type. The dopants of the second conductivity type may be, for instance, aluminum, boron, gallium, indium, or other suitable dopants. The first doped column 150 may be between the second doped columns 160.

In the planar gate MOSFET semiconductor device 100 of FIG. 2, the doped column in the center of the first mesa 135 and the second mesa 140 has n-type dopants. The doped columns at the sides of the first mesa 135 and the second mesa 140 has p-type dopants. For sake of consistency, the p-type dopants are labelled second conductivity type and the n-type dopants are labeled first conductivity type. For purposes of the claims, the p-type dopants may be considered dopants of a first conductivity type and n-type dopants may be considered dopants of a second conductivity type without deviating from the scope of the present disclosure.

In some embodiments, the plurality of first dopants and the plurality of second dopants are such that each of the first mesa 135 and the second mesa 140 is a charge-balanced structure. A charged-balanced structure will have a substantially equal number of dopants (e.g., within 10% of equal) of a first conductivity type (e.g., n-type dopants) and dopants of a second conductivity type (e.g., p-type dopants) in separate doped regions of the structure. For instance, the dopant concentration of the first doped column 150 may be substantially equal to the total combined dopant concentration of the two second doped columns 160 to provide a charge-balanced structure.

The example semiconductor device 200 of FIG. 2 is a superjunction planar gate MOSFET. The semiconductor device 200 has doped surface regions in each of the first mesa 135 and the second mesa 140 to form the superjunction planar gate MOSFET. For instance, each of the first mesa 135 and the second mesa 140 may include a p-type well region 108. The p-type well region 108 may be formed, for instance, by epitaxial growth followed by implantation of p-type dopants. The p-type well regions 108 may be moderately doped with p-type dopants (e.g., aluminum, boron, gallium, indium) at concentrations in a range of about 1×10¹⁶/cm³ to about 1×10¹⁸/cm³, such about 5×10¹⁶/cm³ to about 2×10¹⁷/cm³, such as about 5×10¹⁶/cm³ to about 1×10¹⁷/cm³. In some embodiments, the concentration of dopants in the p-type well regions 108 may be higher than the concentration of dopants in the drift region 106.

An n-type source region 110 may be on the p-well region 108. The source region 110 may be heavily doped with an n-type doping material (n+) at a dopant concentration, for instance, in a range of about 1×10¹⁸/cm³ to about 5×10²¹/cm³, such as about 1×10¹⁹/cm³ to about 1×10²¹/cm³, such as about 5×10¹⁹/cm³ to about 5×10²⁰/cm³. The heavily doped n-type source region 110 may be formed by ion implantation of n-type dopants into the epitaxially formed semiconductor structure 104. However, in some embodiments, the source regions 110 may be formed by epitaxial growth.

The silicon carbide-based semiconductor structure 104 may include one or more p-type contact regions 109 (e.g., p+ regions). The source region 110 may be on the p-type contact regions 109. The p-type contact regions 109 may be more heavily doped with p-type dopants than the p-well regions 108. The p-type contact regions 109 may be formed, for instance, by implantation of p-type dopants into the semiconductor structure 104. However, in some embodiments, the p-type contact regions 109 may be formed by epitaxial growth. The p-type contact regions 109 may be heavily doped with a p-type doping material at concentrations in a range of about 1×10¹⁹/cm³ to 1×10²¹ cm³, such as about 5×10¹⁹/cm³ to 5×10²⁰ cm³, such as about 5×10¹⁹/cm³ to 1×10²⁰ cm³.

A source electrode 112 may be on the n-type source regions 110. The source electrode 112 may provide an ohmic contact with the semiconductor structure 104. The source electrode 112 may include, for example, metals such as nickel, titanium, tantalum, tungsten, aluminum or copper, or alloys or layered stacks of these along with appropriate barrier metals such as tantalum nitride, titanium nitride, titanium tungsten and others, or other suitable materials. In some embodiments, the source electrode 112 may include a separate ohmic contact layer (not shown), for instance, made of nickel silicide that may be formed by depositing a nickel layer which may be annealed into the silicon carbide semiconductor structure 104 to form the nickel silicide ohmic contact.

A drain electrode 116 may be on the lower surface of the substrate 102. The drain electrode 116 may include, for example, similar materials to the source electrode 112, as this forms an ohmic contact to the silicon carbide substrate 102. The drain electrode 116 may include, for example, metals such as nickel, titanium, tungsten, silver, palladium, gold, aluminum or copper, or alloys or layered stacks of these or suitable materials.

A gate structure 130 may be proximate the semiconductor structure 104. A gate dielectric layer 117 may be between the gate structure 130 and the semiconductor structure 104. The gate dielectric layer 117 may insulate the gate structure 130 from the semiconductor structure 104. The gate dielectric layer 117 may be, for instance, an oxide layer. In some examples, the gate dielectric layer 117 includes a silicon dioxide layer or other suitable dielectric between the gate structure 130 and the semiconductor surface. In some embodiments, the gate dielectric layer 117 comprises one or more of SiN, Al₂O₃, MgOₓ, MgNₓ, ZnO, SiNₓ, SiOₓ, HfOₓ or other suitable dielectric layers. A separate interlayer dielectric 136 may be formed over the gate structure 130 to insulate the gate structure 130 from the source electrode 112.

In some embodiments, the gate structure 130 may comprise a metal and/or doped polysilicon. In some examples, the gate structure 130 may be part of a continuous gate pattern including one or more gate buses, gate pads, etc.

The upper portion of each p-type well region 108, which is underneath and overlapping the gate structure 130, may provide a channel region for the MOSFET semiconductor device 120. The drift region 106 may also include a JFET region 106a between the well regions 108 and beneath the gate structure 130 and gate dielectric layer 117. In some embodiments, the JFET region 106a may have a dopant concentration of dopants of the first conductivity type (e.g., n-type dopants) that may be greater than a dopant concentration of the drift region 106. Application of a bias voltage to the gate structure 130 may cause electrons to flow from the source electrode 112 to the drain electrode 116 through source region 110 and through the channel regions to the JFET region 106a, through the first doped column 150 and through the drift region 106 to the drain electrode 116.

In some embodiments, the first doped column 150 of the first conductivity type (e.g., n-type) extends from the JFET region 106a to the drift region 106 such that the JFET region 106a at least partially overlaps the first doped column 150. The second doped columns 160 may extend from the p-well regions 108 to the drift region 106.

As described below, the first doped column 150 may be a non-perpendicular implant defined first doped column formed by implanting dopants at a non-perpendicular angle into the first mesa 135 and the second mesa 140. The second doped columns 160 may be non-perpendicular implant defined second doped column formed by implanting dopants at a non-perpendicular angle into the first mesa 135 and the second mesa 140.

The semiconductor device 200 may further include an insulator layer 126 between the first mesa 135 and the second mesa 140. The insulator layer 126 may be provided on the drift region 106 adjacent to at least one of the first mesa 135 and the second mesa 140. The insulator layer 126 may have a surface that is coplanar with a surface (e.g., a top surface) of the wide bandgap semiconductor structure 104. In some examples, the insulator layer 126 is a silicate glass. For instance, the insulator layer 126 may include a borosilicate glass and/or a borophosphosilicate glass (BPSG). In some examples, the insulator layer 126 is silicon dioxide. Other suitable dielectric or insulating material(s) may be used as the insulator layer 126 without deviating from the scope of the present disclosure. The insulator layer 126 may electrically insulate the first mesa 135 and the second mesa 140.

While the power semiconductor device 200 is an n-type device, aspects of the present disclosure are similarly applicable to p-type devices, and such a device simply replaces the n-type materials with p-type materials and p-type materials with n-type materials.

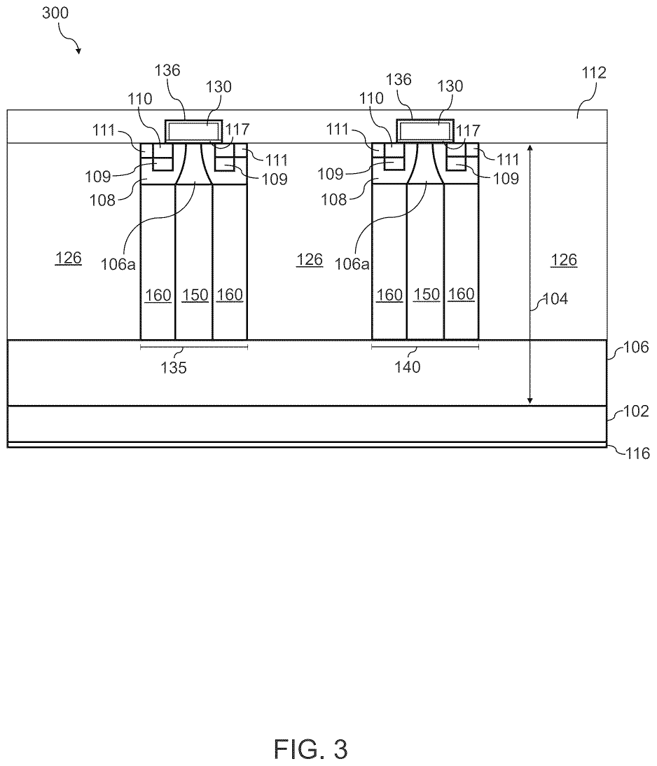

FIG. 3 depicts a cross-sectional view of example unit cells of an example planar gate superjunction MOSFET power semiconductor device 300 according to example embodiments of the present disclosure. The power semiconductor device 300 of FIG. 3 is a silicon carbide-based planar gate superjunction MOSFET. FIG. 3 is intended to represent structures for identification and description and is not intended to represent the structures to physical scale.

The semiconductor device 300 includes many of the same structures and regions as the semiconductor MOSFET 200 of FIG. 2. For instance, the power semiconductor device 300 includes a silicon carbide substrate 102. The power semiconductor device 300 includes a silicon carbide-based semiconductor structure 104 (e.g., epitaxial semiconductor structure) on the silicon carbide substrate 102. The substrate 102 may include, for example, a single crystal 4H silicon carbide semiconductor substrate. The substrate 102 may be heavily doped with n-type dopants (e.g., an n+ silicon carbide substrate). The dopants may comprise, for example, nitrogen or phosphorus or other suitable dopants. The substrate 102 may be any appropriate thickness (e.g., in a range of about 50 microns to about 500 microns, such as about 100 microns to about 360 microns, such as about 200 microns to about 300 microns, but thinner or thicker substrates are possible). Other substrates may be used without deviating from the scope of the present disclosure. The silicon carbide-based semiconductor structure 104 may be epitaxially formed on the substrate 102, for example by chemical vapor deposition (CVD) or other suitable growth techniques. Dopant implantation processes may be used to form doped regions in the semiconductor structure 104 (e.g., n-type regions, p-type regions) as described below.

The silicon carbide-based semiconductor structure 104 may include a doped (e.g., n-doped) silicon carbide drift region 106 on the substrate 102. The silicon carbide drift region 106 may be formed on the substrate 102 by epitaxial growth, for example, by CVD. The drift region 106 of FIG. 3 may have a uniform or nearly uniform dopant concentration across a thickness of the drift region 106. For instance, the drift region 106 may have a uniform or nearly uniform dopant concentration of dopants of a first conductivity type (such that the drift region is an n-type region). However, in other embodiments, the drift region 106 may have a non-uniform dopant concentration, such as a gradient dopant concentration that increases and/or decreases through a thickness of the drift region 106.

The dopant concentration of the drift region 106 may be, for instance, in a range of about 1×10¹⁴/cm³ to about 1×10¹⁷/cm³, such as about 1×10¹⁵/cm³ to about 2×10¹⁶/cm³, such as about 5×10¹⁵/cm³ to about 1×10¹⁶. The dopants may be, for example, nitrogen dopants or phosphorous dopants or any other suitable dopants. The drift region 106 may have a thickness in a range of about 1 micron to about 100 microns, such as about 3 microns to about 100 microns, such as about 6 microns to about 100 microns, such as about 3 microns to about 50 microns, such as about 3 microns to about 20 microns, such as about 4 microns to about 15 microns, such as about 4 microns to about 10 microns.

According to aspects of the present disclosure, the wide bandgap semiconductor structure 104 may include one or more mesas, such as a first mesa 135 and a second mesa 140. The first doped column 150 may be between the two second doped columns 160. Each of the first mesa 135 and the second mesa 140 may be included on a common drift region 106. More particularly, the first mesa 135 and the second mesa 140 may be on the drift region 106. Each of the first mesa 135 and the second mesa 140 may have a height H. The height H of the first mesa 135 and the second mesa 140 may be, for instance, in a range of about 0.5 microns to about 7 microns, such as about 1 micron to about 5 microns, such as about 2 microns to about 4 microns.

The first mesa 135 and the second mesa 140 may include a first doped column 150 of a first conductivity type (e.g., a plurality of n-type dopants, such as nitrogen, phosphorus, or other suitable dopants). The first mesa 135 and the second mesa 140 may include one or more second doped columns 160 of a second conductivity type (e.g., a plurality of p-type dopants), such as two second doped columns 160 of the first conductivity type. The dopants of the second conductivity type may be, for instance, aluminum, boron, gallium, indium, or other suitable dopants. The first doped column 150 may be between the second doped columns 160.

In the planar gate MOSFET semiconductor device 100 of FIG. 2, the doped column in the center of the first mesa 135 and the second mesa 140 has n-type dopants. The doped columns at the sides of the first mesa 135 and the second mesa 140 has p-type dopants. For sake of consistency, the p-type dopants are labelled second conductivity type and the n-type dopants are labeled first conductivity type. For purposes of the claims, the p-type dopants may be considered dopants of a first conductivity type and n-type dopants may be considered dopants of a second conductivity type without deviating from the scope of the present disclosure.

In some embodiments, the plurality of first dopants and the plurality of second dopants are such that each of the first mesa 135 and the second mesa 140 is a charge-balanced structure. A charged-balanced structure will have a substantially equal number of dopants (e.g., within 10% of equal) of a first conductivity type (e.g., n-type dopants) and dopants of a second conductivity type (e.g., p-type dopants) in separate doped regions of the structure. For instance, the dopant concentration of the first doped column 150 may be substantially equal to the total combined dopant concentration of the two second doped columns 160 to provide a charge-balanced structure. The first doped column 150 may be moderately to heavily doped with p-type dopants (e.g., aluminum, boron, gallium, indium) at concentrations in a range of about 1×10¹⁷/cm³ to about 5×10¹⁹/cm³, such about 5×10¹⁷/cm³ to about 1×10¹⁹/cm³, such as about 5×10¹⁷/cm³ to about 5×10¹⁸/cm³. The second doped columns 160 may be moderately to heavily doped with n-type dopants (e.g., nitrogen, phosphorus) at concentrations in a range of about 5×10¹⁶/cm³ to about 2.5×10¹⁹/cm³, such about 2.5×10¹⁷/cm³ to about 5×10¹⁸/cm³, such as about 2.5×10¹⁷/cm³ to about 2.5×10¹⁸/cm³. The two second doped columns 160 contained within each of the first mesa 135 and the second mesa 140 may include a doping level that is about half of the doping level in the first doped column 150. That is, the dopant concentration in the combined lateral width of the two second doped columns 160 may be the same as the dopant concentration in the lateral width of the first doped column 150 so as to keep the total amount of doping in the two second doped columns 160 in balance with the total amount of doping in the first doped column. In some examples, the total width of the two second doped columns 160 may be more or less than about twice the width of the first doped column 150 such that the total doping of each of the two second doped columns 160 may be adjusted, for example by implant dosing, inversely proportional to the ratio of the total width of the two second doped columns 160 to the width of the first doped column 150, so as to maintain a charge balanced structure within the first mesa 135 or the second mesa 140.

The example semiconductor device 300 of FIG. 3 is a superjunction planar gate MOSFET. The semiconductor device 300 has doped surface regions in each of the first mesa 135 and the second mesa 140 to form the superjunction planar gate MOSFET. For instance, each of the first mesa 135 and the second mesa 140 may include a p-type well region 108. The p-type well region 108 may be formed, for instance, by epitaxial growth followed by implantation of p-type dopants. The p-type well regions 108 may be moderately doped with p-type dopants (e.g., aluminum, boron, gallium, indium) at concentrations in a range of about 1×10¹⁶/cm³ to about 1×10¹⁸/cm³, such about 5×10¹⁶/cm³ to about 2×10¹⁷/cm³, such as about 5×10¹⁶/cm³ to about 1×10¹⁷/cm³. In some embodiments, the concentration of dopants in the p-type well regions 108 may be higher than the concentration of dopants in the drift region 106.

An n-type source region 110 may be on the p-well region 108. The source region 110 may be heavily doped with an n-type doping material (n+) at a dopant concentration, for instance, in a range of about 1×10¹⁸/cm³ to about 5×10²¹/cm³, such as about 1×10¹⁹/cm³ to about 1×10²¹/cm³, such as about 5×10¹⁹/cm³ to about 5×10²⁰/cm³. The heavily doped n-type source region 110 may be formed by ion implantation of n-type dopants into the epitaxially formed semiconductor structure 104. However, in some embodiments, the source regions 110 may be formed by epitaxial growth.

The silicon carbide-based semiconductor structure 104 may include one or more p-type contact regions 109 (e.g., p+ regions). The source region 110 may be on the p-type contact regions 109. The p-type contact regions 109 may be more heavily doped with p-type dopants than the p-well regions 108. The p-type contact regions 109 may be formed, for instance, by implantation of p-type dopants into the semiconductor structure 104. However, in some embodiments, the p-type contact regions 109 may be formed by epitaxial growth. The p-type contact regions 109 may be heavily doped with a p-type doping material at concentrations in a range of about 1×10¹⁹/cm³ to 1×10²¹ cm³, such as about 5×10¹⁹/cm³ to 5×10²⁰ cm³, such as about 5×10¹⁹/cm³ to 1×10²⁰ cm³.

The silicon carbide-based semiconductor structure 104 may include one or more p-type contact regions 111 (e.g., p+ regions). The source region 110 may be laterally adjacent to the p-type contact regions 111. The p-type contact regions 111 may be more heavily doped with p-type dopants than the p-well regions 108. The p-type contact regions 111 may be formed, for instance, by implantation of p-type dopants into the semiconductor structure 104. However, in some embodiments, the p-type contact regions 111 may be formed by epitaxial growth. The p-type contact regions 111 may be heavily doped with a p-type doping material at concentrations in a range of about 1×10¹⁹/cm³ to 1×10²¹ cm³, such as about 5×10¹⁹/cm³ to 5×10²⁰ cm³, such as about 5×10¹⁹/cm³ to 1×10²⁰ cm³.

A source electrode 112 may be on the n-type source regions 110. The source electrode 112 may provide an ohmic contact with the semiconductor structure 104. The source electrode 112 may include, for example, metals such as nickel, titanium, tantalum, tungsten, aluminum or copper, or alloys or layered stacks of these along with appropriate barrier metals such as tantalum nitride, titanium nitride, titanium tungsten and others, or other suitable materials. In some embodiments, the source electrode 112 may include a separate ohmic contact layer (not shown), for instance, made of nickel silicide that may be formed by depositing a nickel layer which may be annealed into the silicon carbide semiconductor structure 104 to form the nickel silicide ohmic contact.

A drain electrode 116 may be on the lower surface of the substrate 102. The drain electrode 116 may include, for example, similar materials to the source electrode 112, as this forms an ohmic contact to the silicon carbide substrate 102. The drain electrode 116 may include, for example, metals such as nickel, titanium, tungsten, silver, palladium, gold, aluminum or copper, or alloys or layered stacks of these or suitable materials.

A gate structure 130 may be proximate the semiconductor structure 104. A gate dielectric layer 117 may be between the gate structure 130 and the semiconductor structure 104. The gate dielectric layer 117 may insulate the gate structure 130 from the semiconductor structure 104. The gate dielectric layer 117 may be, for instance, an oxide layer. In some examples, the gate dielectric layer 117 includes a silicon dioxide layer or other suitable dielectric between the gate structure 130 and the semiconductor surface. In some embodiments, the gate dielectric layer 117 comprises one or more of SiN, Al₂O₃, MgOₓ, MgNₓ, ZnO, SiNₓ, SiOₓ, HfOₓ or other suitable dielectric layers. A separate interlayer dielectric 136 may be formed over the gate structure 130 to insulate the gate structure 130 from the source electrode 112.

In some embodiments, the gate structure 130 may comprise a metal and/or doped polysilicon. In some examples, the gate structure 130 may be part of a continuous gate pattern including one or more gate buses, gate pads, etc.

The upper portion of each p-type well region 108, which is underneath and overlapping the gate structure 130, may provide a channel region for the MOSFET semiconductor device 120. The drift region 106 may also include a JFET region 106a between the well regions 108 and beneath the gate structure 130 and gate dielectric layer 117. In some embodiments, the JFET region 106a may have a dopant concentration of dopants of the first conductivity type (e.g., n-type dopants) that may be greater than a dopant concentration of the drift region 106. Application of a bias voltage to the gate structure 130 may cause electrons to flow from the source electrode 112 to the drain electrode 116 through source region 110 and through the channel regions to the JFET region 106a, through the first doped column 150 and through the drift region 106 to the drain electrode 116.

In some embodiments, the first doped column 150 of the first conductivity type (e.g., n-type) extends from the JFET region 106a to the drift region 106 such that the JFET region 106a at least partially overlaps the first doped column 150. As described below, the first doped column 150 may be a non-perpendicular implant defined first doped column formed by implanting dopants at a non-perpendicular angle into the first mesa 135 and the second mesa 140. The second doped columns 160 may be non-perpendicular implant defined second doped column formed by implanting dopants at a non-perpendicular angle into the first mesa 135 and the second mesa 140.

The semiconductor device 300 may further include an insulator layer 126 between the first mesa 135 and the second mesa 140. The insulator layer 126 may be provided on the drift region 106 adjacent to at least one of the first mesa 135 and the second mesa 140. The insulator layer 126 may have a surface that is coplanar with a surface (e.g., a top surface) of the wide bandgap semiconductor structure 104. In some examples, the insulator layer 126 is a silicate glass. For instance, the insulator layer 126 may include a borosilicate glass and/or a borophosphosilicate glass (BPSG). In some examples, the insulator layer 126 is silicon dioxide. Other suitable dielectric or insulating material(s) may be used as the insulator layer 126 without deviating from the scope of the present disclosure. The insulator layer 126 may electrically insulate the first mesa 135 and the second mesa 140.

While the power semiconductor device 300 is an n-type device, aspects of the present disclosure are similarly applicable to p-type devices, and such a device simply replaces the n-type materials with p-type materials and p-type materials with n-type materials.

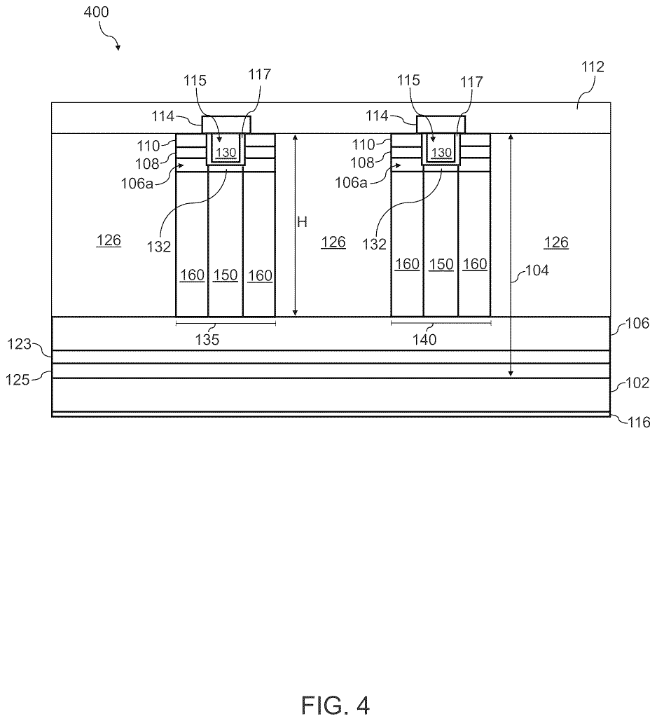

Any of the foregoing embodiments may be incorporated into different types of semiconductor devices, such as IGBTs. For instance, FIG. 4 depicts a trench gate superjunction IGBT 400 having a construction similar to that of the MOSFET semiconductor device 100 of FIG. 1. However, the IGBT 400 includes a field stop layer 123 in the semiconductor structure 104 that is moderately doped with dopants of a first conductivity type (e.g., n-type). The IGBT 400 further includes an emitter layer 125 in the semiconductor structure that is highly doped with dopants of a second conductivity type (e.g., p-type). As shown in FIG. 4, the IGBT 160 has a first mesa 135 and a second mesa 140 that are charge-balanced structures similar to the semiconductor device 100 of FIG. 1.

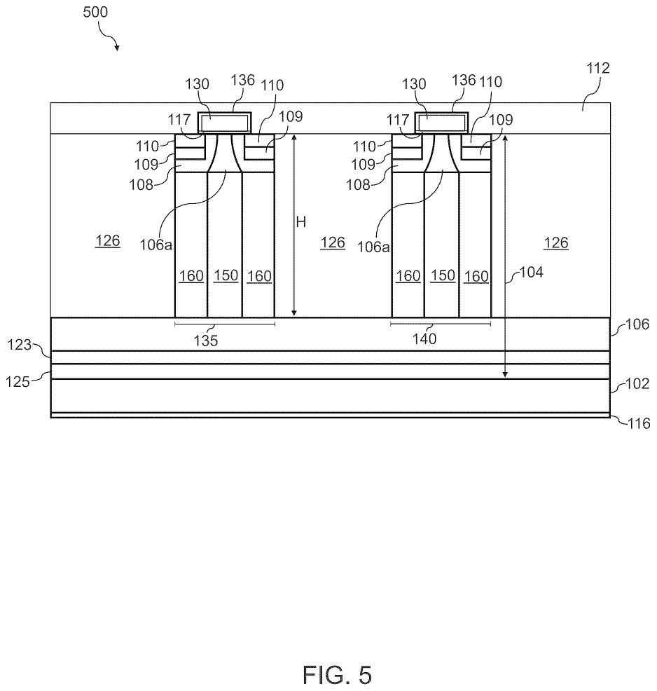

FIG. 5 depicts a planar gate superjunction IGBT 500 having a construction similar to that of the MOSFET semiconductor device 200 of FIG. 2. However, the IGBT 500 includes a field stop layer 123 in the semiconductor structure 104 that is moderately doped with dopants of a first conductivity type (e.g., n-type). The IGBT 500 further includes an emitter layer 125 in the semiconductor structure that is highly doped with dopants of a second conductivity type (e.g., p-type). As shown in FIG. 5, the IGBT 160 has a first mesa 135 and a second mesa 140 that are charge-balanced structures similar to the semiconductor device 200 of FIG. 2.

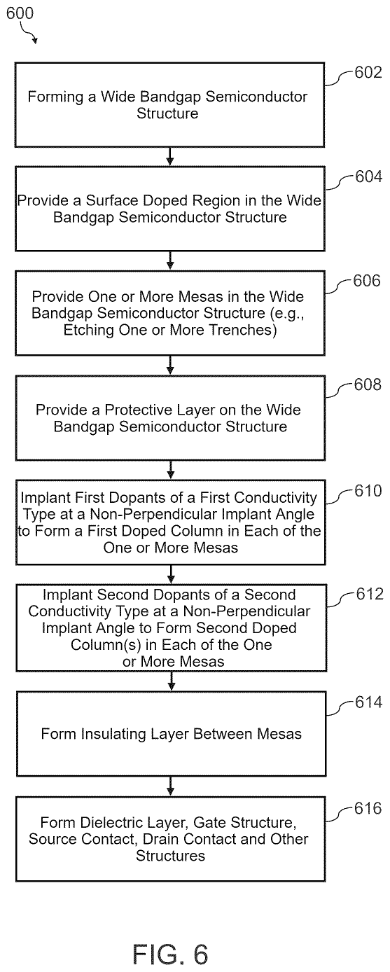

FIG. 6 depicts a flow chart diagram of an example method 600 for fabricating a semiconductor device according to example embodiments of the present disclosure. FIG. 6 depicts example process steps for purposes of illustration and discussion. Those of ordinary skill in the art, using the disclosures provided herein, will understand that process steps of any of the methods described in the present disclosure may be adapted, modified, include steps not illustrated, omitted, and/or rearranged without deviating from the scope of the present disclosure.

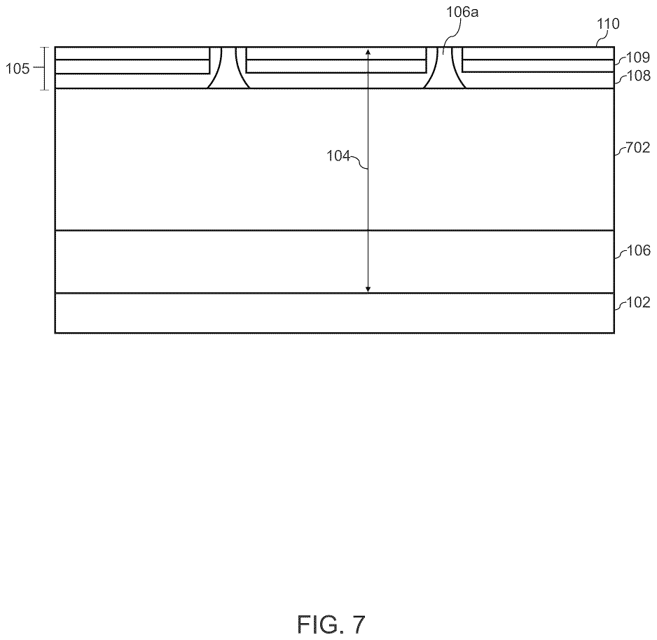

At 602, the method 600 may include forming a wide bandgap semiconductor structure (e.g., silicon carbide semiconductor structure) on a substrate (e.g., a silicon carbide substrate). For instance, as shown in FIG. 7, the method 600 may include forming the wide bandgap semiconductor structure 104 on the substrate 102. The wide bandgap semiconductor structure 104 may be formed, for instance, using epitaxial growth of the drift region 106 and/or a graded drift region 702.

The silicon carbide-based semiconductor structure 104 may include a doped (e.g., n-doped) silicon carbide drift region 106 on the substrate 102. The substrate 102 may include, for example, a single crystal 4H silicon carbide semiconductor substrate. The substrate 102 may be heavily doped with n-type dopants (e.g., an n+ silicon carbide substrate). The dopants may comprise, for example, nitrogen or phosphorus or other suitable dopants. The substrate 102 may be any appropriate thickness (e.g., in a range of about 50 microns to about 500 microns, such as about 100 microns to about 360 microns, such as about 200 microns to about 300 microns, but thinner or thicker substrates are possible). Other substrates may be used without deviating from the scope of the present disclosure.

The silicon carbide drift region 106 may be formed on the substrate 102 by epitaxial growth, for example, by CVD. The drift region 106 of FIG. 7 may have a uniform or nearly uniform dopant concentration across a thickness of the drift region 106. For instance, the drift region 106 may have a uniform or nearly uniform dopant concentration of dopants of a first conductivity type (such that the drift region is an n-type region). However, in other embodiments, the drift region 106 may have a non-uniform dopant concentration, such as a graded dopant concentration (e.g., a graded drift region 702) that increases and/or decreases through a thickness of the drift region 106.

The dopant concentration of the drift region 106 may be, for instance, in a range of about 1×10¹⁴/cm³ to about 1×10¹⁷/cm³, such as about 1×10¹⁵/cm³ to about 2×10¹⁶/cm³, such as about 5×10¹⁵/cm³ to about 1×10¹⁶. The dopants may be, for example, nitrogen dopants or phosphorous dopants or other suitable dopants. The drift region 106 may have a thickness in a range of about 1 micron to about 100 microns, such as about 3 microns to about 100 microns, such as about 6 microns to about 100 microns, such as about 3 microns to about 50 microns, such as about 3 microns to about 20 microns, such as about 4 microns to about 15 microns, such as about 4 microns to about 10 microns.

Referring to FIG. 6 at 604, the method 600 may include forming a doped surface region. For instance, as shown in FIG. 7, the semiconductor structure 104 may have a doped surface region 105. The doped surface region 105 may include a p-type well region 108. The p-type well region 108 may be formed, for instance, by epitaxial growth followed by implantation of p-type dopants. The p-type well regions 108 may be moderately doped with p-type dopants (e.g., aluminum, boron, gallium, indium) at concentrations in a range of about 1×10¹⁶/cm³ to about 1×10¹⁸/cm³, such about 5×10¹⁶/cm³ to about 2×10¹⁷/cm³, such as about 5×10¹⁶/cm³ to about 1×10¹⁷/cm³. In some embodiments, the concentration of dopants in the p-type well regions 108 may be higher than the concentration of dopants in the drift region 106.

An n-type source region 110 may be on the p-well region 108. The source region 110 may be heavily doped with an n-type doping material (n+) at a dopant concentration, for instance, in a range of about 1×10¹⁸/cm³ to about 5×10²¹/cm³, such as about 1×10¹⁹/cm³ to about 1×10²¹/cm³, such as about 5×10¹⁹/cm³ to about 5×10²⁰/cm³. The heavily doped n-type source region 110 may be formed by ion implantation of n-type dopants into the epitaxially formed semiconductor structure 104. However, in some embodiments, the source regions 110 may be formed by epitaxial growth.

The silicon carbide-based semiconductor structure 104 may include one or more p-type regions 109 (e.g., p+ regions). The source region 109 may be on the p-type regions 109. The p-type regions 109 may be more heavily doped with p-type dopants than the p-well regions 108. The p-type regions 109 may be formed, for instance, by implantation of p-type dopants into the semiconductor structure 104. However, in some embodiments, the p-type regions 109 may be formed by epitaxial growth. The p-type contact regions 109 may be heavily doped with a p-type doping material at concentrations in a range of about 1×10¹⁹/cm³ to 1×10²¹ cm³, such as about 5×10¹⁹/cm³ to 5×10²⁰ cm³, such as about 5×10¹⁹/cm³ to 1×10²⁰ cm³.

The drift region 106 may also include a JFET region 106a between the well regions 108. In some embodiments, the JFET region 106a may have a dopant concentration of dopants of the first conductivity type (e.g., n-type dopants) that may be greater than a dopant concentration of the drift region 106.

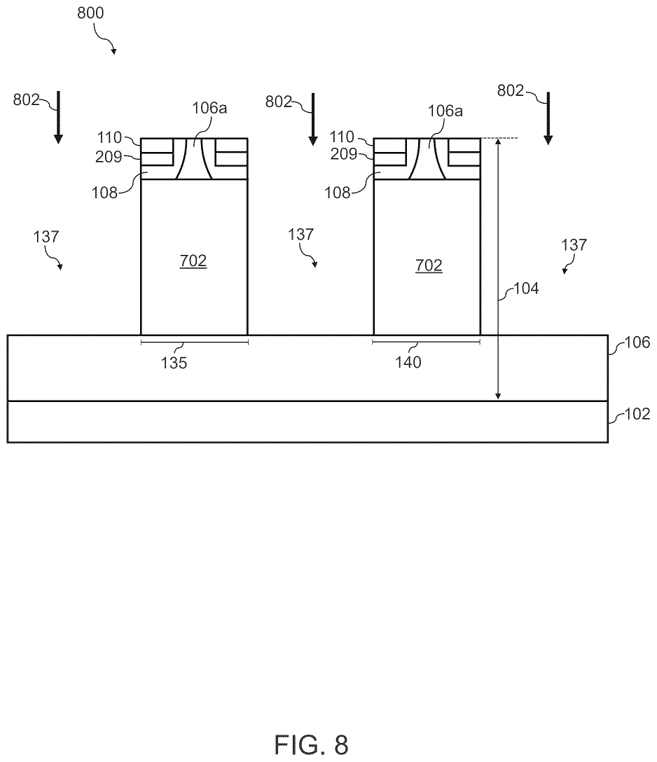

Referring now to FIG. 6, at 606, the method 600 may include providing the first mesa and the second mesa in the wide bandgap semiconductor structure. For instance, the method may include etching the semiconductor structure 104 using an etching process to form trenches in the semiconductor structure 104. For instance, as shown in FIG. 8, the method may include performing an etching process 802 to form trenches 137 in the semiconductor structure 104, resulting in formation of the first mesa 135 and the second mesa 140 in the wide bandgap semiconductor structure 104. The etching process 802 may be any suitable wet etching, dry etching, or other etching process suitable to form the first mesa 135 and the second mesa 140. The etching process 802 may utilize a mask (not shown) to protect features of the wide-bandgap semiconductor structure 104 in forming the first mesa 135 and the second mesa 140. The mask may be removed once the etching process 802 is completed.

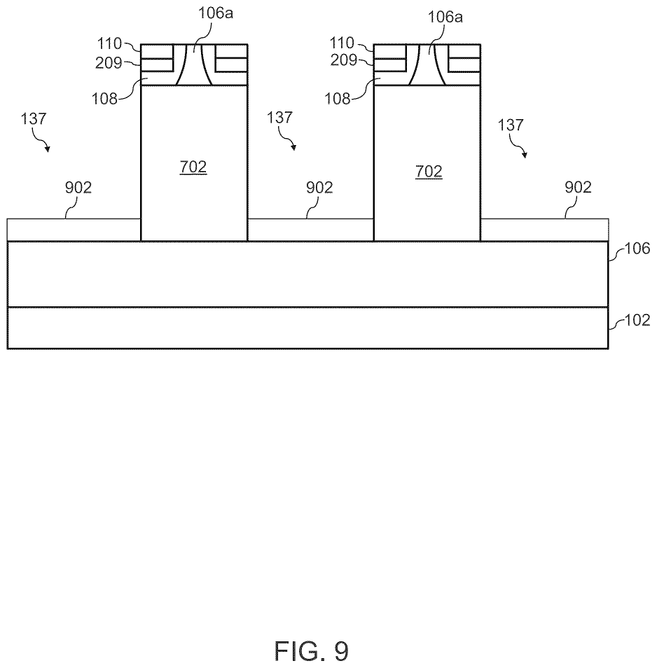

Referring now to FIG. 6, the method 600 at 608 optionally includes providing a protective layer or a passivation layer in the trenches on the drift region. For instance, as shown in FIG. 9, the method may include depositing a protective layer 902 (e.g., a passivation layer) on the drift region 106 in the trenches 137 between the mesas formed in the semiconductor structure 104. The protective layer 902 may include a borosilicate glass and/or a borophosphosilicate glass (BPSG), or any other suitable material to protect the drift region 106 in a subsequent dopant implantation process.

Referring now to FIG. 6, the method 600 at 610 includes implanting first dopants of a first conductivity type at a non-perpendicular implant angle to form a first doped column in each of the one or more mesas. A non-perpendicular implant angle refers to an implant angle relative to an axis parallel to a top surface of the mesas or the semiconductor structure that is not 90 degrees. Implanting first dopants at a non-perpendicular implant angle may provide a non-perpendicular implant angle defined first doped column in the one or more mesas.

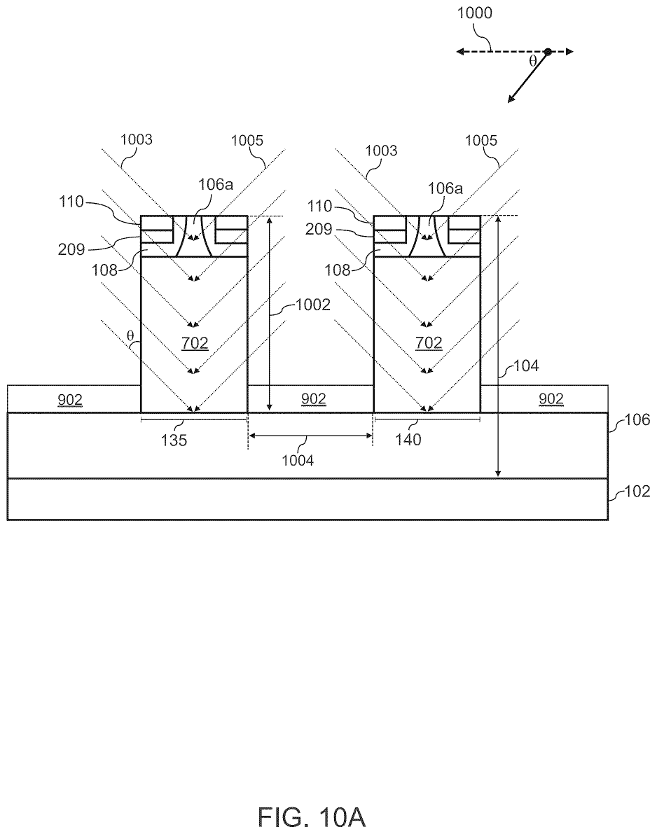

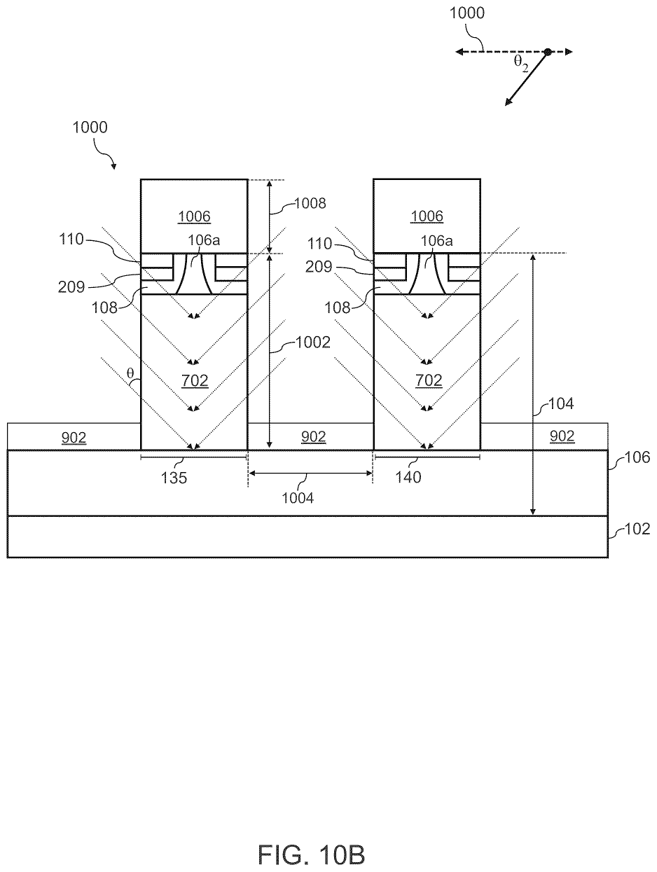

For instance, FIG. 10A depicts by dashed arrows the implantation of dopants into the first mesa 135 and the second mesa 140 at a non-perpendicular implant angle θ1 relative to axis 1000, which is parallel to the top surface of the first mesa 135 and the second mesa 140. In some examples, the non-perpendicular implant angle θ1 is in a range of about 10 degrees to about 80 degrees, such as about 15 degrees to about 75 degrees, such as about 30 degrees to about 60 degrees.

As shown in FIG. 10A, implants may be provided to the center portion of the first mesa 135 and the second mesa 140 to form a first doped column 150 as illustrated in FIGS. 1-3. The dopants may be implanted at a non-perpendicular implant angle from a first direction 1003 and from a second direction 1005. The first direction 1003 is different from the second direction 1005. The non-perpendicular implant angle θ1 is mirrored with respect to a vertical axis of the first mesa 135 and the second mesa 140

In some embodiments, the implant angle θ1 may be a function of a trench depth 1002 and a trench width 1004. In some embodiments, the implant angle θ1 may be determined based at least in part on the arctangent of the trench width 1004 over the trench depth 1002.

The implantation of dopants shown in FIG. 10A to form the first doped column may be associated with a first implant dosage and first implant energy. The first implant energy may be sufficient for dopants to be implanted in a center portion of the first mesa 135 and the second mesa 140 to form the first doped column. The first implant dosage may be sufficient to provide a dopant concentration for the first doped column in a range of about 1×10¹⁷/cm³ to about 5×10¹⁹/cm³.

As shown in FIG. 10B, in some embodiments, a hard mask 1006 may be used to protect portions of the wide-bandgap semiconductor structure 104, such as the doped portions near the surface of the first mesa 135 and the second mesa 140. In such embodiments, the implant angle θ2 may be different than the implant angle θ1, such as greater or less than the implant angle θ1. In some embodiments, the implant angle θ2 may be determined based at least in part on an arctangent of the trench width 1004 over the sum of a hard mask thickness 1008 and the trench depth 1002.

Referring now to FIG. 6, the method 600 at 612 includes implanting second dopants of a second conductivity type at a non-perpendicular implant angle to form second doped column(s) in each of the one or more mesas. Implanting second dopants at a non-perpendicular implant angle may provide a non-perpendicular implant angle defined second doped column in the one or more mesas.

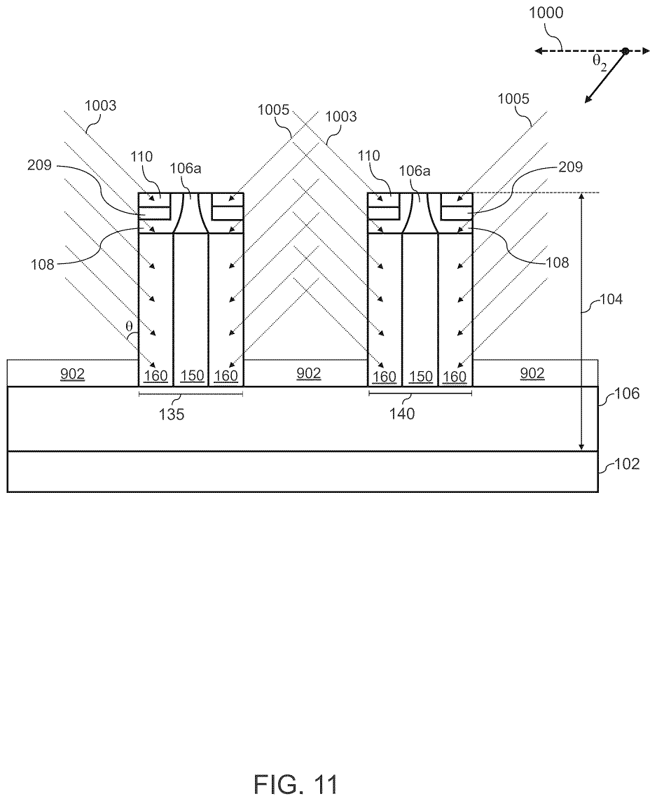

For instance, FIG. 11 depicts by dashed arrows the implantation of dopants into the first mesa 135 and the second mesa 140 at a second non-perpendicular implant angle θ3 relative to axis 1000, which is parallel to the top surface of the first mesa 135 and the second mesa 140. In some examples, the non-perpendicular implant angle θ3 is in a range of about 10 degrees to about 80 degrees, such as about 15 degrees to about 75 degrees, such as about 30 degrees to about 60 degrees. The implantation of dopants at the non-perpendicular implant angle θ3 may form the second doped columns 150.

In some embodiments, the non-perpendicular implant angle θ3 is the same as the non-perpendicular implant angle θ1 used to implant dopants into the first doped column. In some embodiments, the non-perpendicular implant angle θ3 is different the non-perpendicular implant angle θ1 used to implant dopants into the first doped column 150. For instance, the non-perpendicular implant angle θ3 may be larger than the non-perpendicular implant angle θ1. In some cases, the non-perpendicular implant angle θ3 may be smaller than the non-perpendicular implant angle θ1.

As shown in FIG. 11, implants may be provided to the edge portions of the first mesa 135 and the second mesa 140 to form second doped columns 160 as illustrated in FIGS. 1-3. The dopants may be implanted at a non-perpendicular implant angle from a first direction 1003 and from a second direction 1005. The first direction 1003 is different from the second direction 1005. The non-perpendicular implant angle θ3 is mirrored with respect to a vertical axis of the first mesa 135 and the second mesa 140

In some embodiments, the implant angle θ3 may be a function of a trench depth 1002 and a trench width 1004. In some embodiments, the implant angle θ1 may be determined based at least in part on the arctangent of the trench width 1004 over the trench depth 1002.

The implantation of dopants shown in FIG. 11 to form the second doped columns 16—may be associated with a second implant dosage and second implant energy. The second implant energy may be the same or different than the first implant energy, such as less the first implant energy. The second implant energy may be sufficient for dopants to be implanted in an edge portion of the first mesa 135 and the second mesa 140 to form the second doped columns 160. The second implant dosage may be sufficient to provide a dopant concentration for the first doped column in a range of about 5×10¹⁶/cm³ to about 2.5×10¹⁹/cm³. The second implant dosage may be such each of the first mesa 135 and the second mesa 140 is a charge-balanced structure.

Referring now to FIG. 6, the method 600 at 614 includes providing an insulator layer between the one or more mesas (e.g., providing the insulator in the trenches between the one or more mesas). In some embodiments, the protective layer 902 may optionally be removed before depositing the insulator layer.

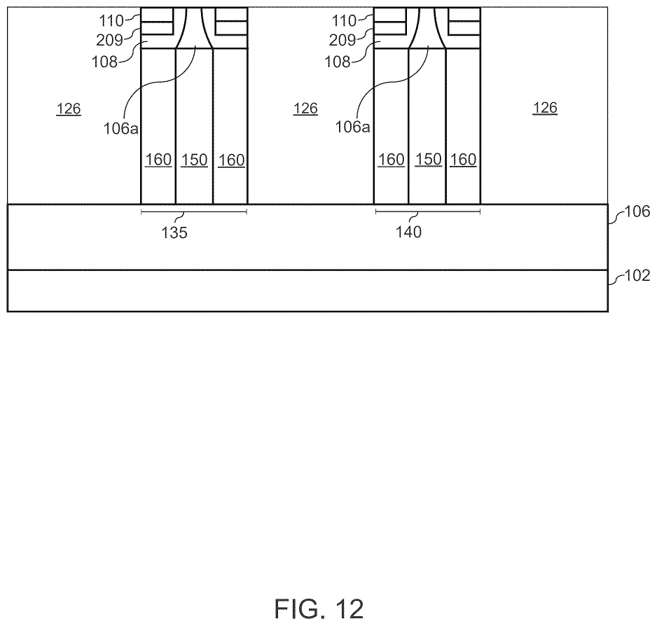

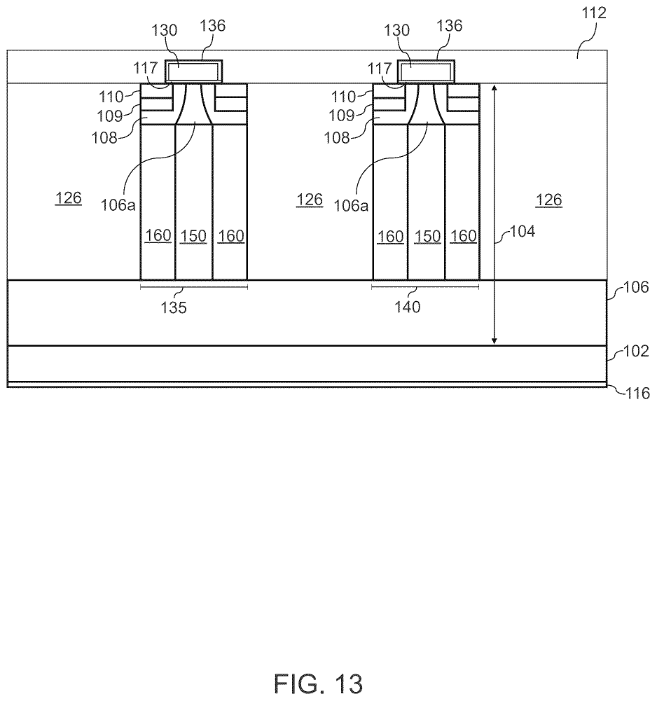

For instance, FIG. 12 shows an insulator layer 126 deposited in the trenches 137 adjacent the first mesa 135 and the second mesa 140. The insulator layer 126 may be deposited using any suitable deposition process, such as a chemical vapor deposition (CVD) process, a physical vapor deposition (PVD) process, a sputtering process, an atomic layer deposition (ALD) process, or other suitable deposition process. The insulator layer 126 may have a surface that is coplanar with a surface (e.g., a top surface) of the wide bandgap semiconductor structure 104. In some examples, the insulator layer 126 may be an oxide, such as silicon dioxide. In some examples, the insulator layer 126 is a silicate glass. For instance, the insulator layer 126 may include a borosilicate glass and/or a borophosphosilicate glass (BPSG). Other suitable dielectric or insulating material(s) may be used as the insulator layer 126 without deviating from the scope of the present disclosure.

Referring to FIG. 6 at 614, the method 600 may include forming the remaining components of the semiconductor device, such as formation of the gate dielectric, gate structure, source electrode, drain electrode, and other structures. Details concerning these example structures are discussed with reference to FIGS. 1-3 above.

Example aspects of the present disclosure are set forth below. Any of the below features or examples may be used in combination with any of the embodiments or features provided in the present disclosure.

In an aspect, the present disclosure provides an example semiconductor device. In some implementations, the example semiconductor device includes a wide bandgap semiconductor structure having a first mesa and a second mesa. In some implementations, the example semiconductor device includes a dielectric between the first mesa and the second mesa. In some implementations, each of the first mesa and the second mesa includes a first doped column, the first doped column comprising a plurality of first dopants of a first conductivity type, wherein each of the first mesa and the second mesa comprise two second doped columns, each second doped column comprising a plurality of second dopants of a second conductivity type.

In some implementations of the example semiconductor device, the plurality of first dopants and the plurality of second dopants are such that each of the first mesa and the second mesa is a charge-balanced structure.

In some implementations of the example semiconductor device, each of the first mesa and the second mesa is on a common drift region.

In some implementations of the example semiconductor device, the wide bandgap semiconductor structure is on a substrate.

In some implementations of the example semiconductor device, the semiconductor device includes a drain electrode on the substrate.

In some implementations of the example semiconductor device, each of the first mesa and the second mesa includes a source region.

In some implementations of the example semiconductor device, the semiconductor device includes a contact region.

In some implementations of the example semiconductor device, the source region is on the contact region.

In some implementations of the example semiconductor device, the source region is laterally adjacent the contact region.

In some implementations of the example semiconductor device, the semiconductor device further comprises a source electrode on the source region.

In some implementations of the example semiconductor device, each of the first mesa and the second mesa includes a JFET region, wherein the JFET region is at least partially vertically aligned with the first doped column.

In some implementations of the example semiconductor device, the semiconductor device further comprises a planar gate structure on each of the first mesa and the second mesa.

In some implementations of the example semiconductor device, the semiconductor device further comprises a trench gate structure in each of the first mesa and the second mesa.

In some implementations of the example semiconductor device, each of the first mesa and the second mesa includes a well region.

In some implementations of the example semiconductor device, the two second doped columns for each of the first mesa and the second mesa extends from the well region to a drift region.

In some implementations of the example semiconductor device, each of the first mesa and the second mesa have a height in a range of about 1 micron to about 5 microns.

In some implementations of the example semiconductor device, the dielectric includes silicon dioxide.

In some implementations of the example semiconductor device, the dielectric includes a silicate glass.

In some implementations of the example semiconductor device, the first dopants comprise n-type dopants and the second dopants comprise p-type dopants, wherein the first doped column is between the two second doped columns.

In some implementations of the example semiconductor device, the first dopants comprise p-type dopants and the second dopants comprise n-type dopants, wherein the first doped column is between the two second doped columns.

In some implementations of the example semiconductor device, the wide bandgap semiconductor structure includes silicon carbide.

In some implementations of the example semiconductor device, the semiconductor device is a MOSFET or an IGBT.

In an aspect, the present disclosure provides an example method of fabricating a semiconductor device. In some implementations, the example method of fabricating a semiconductor device includes providing a wide bandgap semiconductor structure on a substrate. In some implementations, the example method of fabricating a semiconductor device includes providing one or more mesas in the wide bandgap semiconductor structure. In some implementations, the example method of fabricating a semiconductor device includes implanting dopants at a non-perpendicular implant angle into each of the one or more mesas.

In some implementations of the example method, the method includes providing one or more mesas in the wide bandgap semiconductor structure includes etching trenches in the wide bandgap semiconductor structure.

In some implementations of the example method, the non-perpendicular implant angle is in a range of about 15 degrees to about 75 degrees from a vertical axis.

In some implementations of the example method, implanting dopants at a non-perpendicular implant angle into each of the one or more mesas includes implanting dopants into a first side of the mesa from a first direction and implanting dopants into a second side of the mesa from a second direction.

In some implementations of the example method, implanting dopants at a non-perpendicular implant angle into each of the one or more mesas includes implanting first dopants of a first conductivity type to form a first doped column in each of the one or more mesas. In some implementations of the example method, implanting dopants at a non-perpendicular implant angle into each of the one or more mesas includes implanting second dopants of a second conductivity type to form two second doped columns in each of the one or more mesas.

In some implementations of the example method, implanting first dopants is associated with a first implant energy and a first implant dosage and implanting second dopants is associated with a second implant energy and a second implant dosage.

In some implementations of the example method, the first implant energy is different than the second implant energy.

In some implementations of the example method, implanting first dopants is associated with a first non-perpendicular implant angle and implanting second dopants is associated with a second non-perpendicular implant angle relative to a vertical axis of the mesa, wherein the first non-perpendicular implant angle is different than the second non-perpendicular implant angle.

In some implementations of the example method, the first non-perpendicular implant angle is larger than the second non-perpendicular implant angle.

In some implementations of the example method, the second non-perpendicular implant angle is larger than the first non-perpendicular implant angle.

In some implementations of the example method, the first implant dosage and the second implant dosage is such that each of the one or more mesas is a charge-balanced structure.

In some implementations of the example method, the method comprises providing a surface doped region in the one or more mesas in an ion-based implantation process.

In some implementations of the example method, the surface doped region includes one or more of a source region, a well region, or a JFET region.

In some implementations of the example method, implanting dopants at the non-perpendicular implant angle into each of the one or more mesas further includes implanting dopants at the non-perpendicular implant angle from a first direction and implanting dopants at the non-perpendicular implant angle from a second direction, wherein the first direction is different than the second direction and the non-perpendicular implant angle is mirrored with respect to a vertical axis of the mesa.

In some implementations of the example method, the method includes providing a passivation layer on the semiconductor structure prior to implanting dopants at a non-perpendicular implant angle.

In some implementations of the example method, the method includes providing a mask layer on the one or more mesas prior to implanting dopants at a non-perpendicular implant angle.

In some implementations of the example method, the method includes providing a dielectric adjacent the one or more mesas after implanting dopants at a non-perpendicular implant angle.

In some implementations of the example method, the dielectric includes silicon dioxide.

In some implementations of the example method, the dielectric includes a silicate glass.

In some implementations of the example method, each of the one or more mesas has a height in a range of about 1 micron to about 5 microns.

In some implementations of the example method, the method includes determining the non-perpendicular implant angle based at least in part on a height of the one or more mesas.

In some implementations of the example method, the method includes determining the non-perpendicular implant angle based at least in part on a width between the one or more mesas.

In some implementations of the example method, the wide bandgap semiconductor structure includes silicon carbide.

In some implementations of the example method, the semiconductor device is a MOSFET.

In some implementations of the example method, the semiconductor device is an IGBT.

In an aspect, the present disclosure provides an example semiconductor device. In some implementations, the example semiconductor device includes a substrate. In some implementations, the example semiconductor device includes a wide bandgap semiconductor structure, the semiconductor structure comprising a drift region and at least one mesa on the drift region. In some implementations, the example semiconductor device includes a first doped column in the mesa, the first doped column comprising dopants of a first conductivity type. In some implementations, the example semiconductor device includes two second doped columns in the mesa, the second doped columns comprising dopants of a second conductivity type. In some implementations, the example semiconductor device includes a gate structure on the mesa. In some implementations, the first doped column is between the two second doped columns, wherein the first doped column and the two second doped column provide a charge-balanced structure.

In some implementations of the example semiconductor device, the first doped column is a non-perpendicular implant defined first doped column and the two second doped columns are non-perpendicular implant defined second doped columns.

In some implementations of the example semiconductor device, the gate structure is a planar gate structure, wherein the planar gate structure is on a surface of the mesa.

In some implementations of the example semiconductor device, the gate structure is a trench gate structure, wherein the trench gate structure is in a trench in the mesa.

In some implementations of the example semiconductor device, the semiconductor device comprises an additional mesa on the drift region, the additional mesa being spaced apart from the mesa.

In some implementations of the example semiconductor device, the semiconductor device comprises a dielectric between the mesa and the additional mesa.

In some implementations of the example semiconductor device, the dielectric includes silicon dioxide.

In some implementations of the example semiconductor device, the dielectric includes a silicate glass.

In some implementations of the example semiconductor device, the semiconductor device comprises a drain electrode on the substrate.

In some implementations of the example semiconductor device, the semiconductor device comprises a source region in the mesa, the source region comprising a first region having a plurality of first dopants of the first conductivity type and a second region having a plurality of second dopants of the second conductivity type.

In some implementations of the example semiconductor device, the first region is on the second region.

In some implementations of the example semiconductor device, the source region further includes a third region having a plurality of second dopants of the second conductivity type, the third region being laterally adjacent the first region.

In some implementations of the example semiconductor device, the semiconductor device comprises a source electrode on the source region.

In some implementations of the example semiconductor device, the mesa includes a JFET region.

In some implementations of the example semiconductor device, the JFET region is at least partially vertically aligned with the first doped column.

In some implementations of the example semiconductor device, the JFET region is at least partially vertically aligned with at least one of the second doped columns.

In some implementations of the example semiconductor device, the mesa has a height in a range of about 1 micron to about 5 microns.

In some implementations of the example semiconductor device, the first dopants comprise n-type dopants and the second dopants comprise p-type dopants.

In some implementations of the example semiconductor device, the first dopants comprise p-type dopants and the second dopants comprise n-type dopants.

In some implementations of the example semiconductor device, the wide bandgap semiconductor structure includes silicon carbide.

In some implementations of the example semiconductor device, the semiconductor device is a MOSFET or an IGBT.

While the present subject matter has been described in detail with respect to specific example embodiments thereof, it will be appreciated that those skilled in the art, upon attaining an understanding of the foregoing can readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A semiconductor device, comprising:
a wide bandgap semiconductor structure having a first mesa and a second mesa;
a dielectric between the first mesa and the second mesa;
wherein each of the first mesa and the second mesa comprises a first doped column, the first doped column comprising a plurality of first dopants of a first conductivity type, wherein each of the first mesa and the second mesa comprise two second doped columns, each second doped column comprising a plurality of second dopants of a second conductivity type.

2. The semiconductor device of claim 1, wherein the plurality of first dopants and the plurality of second dopants are such that each of the first mesa and the second mesa is a charge-balanced structure.

3. The semiconductor device of claim 1, wherein each of the first mesa and the second mesa is on a common drift region.

4. The semiconductor device of claim 1, wherein the wide bandgap semiconductor structure is on a substrate.

5. The semiconductor device of claim 1, wherein each of the first mesa and the second mesa comprises a source region and a contact region.

6. The semiconductor device of claim 5, wherein the source region is on the contact region.

7. The semiconductor device of claim 5, wherein the source region is laterally adjacent the contact region.

8. The semiconductor device of claim 1, wherein each of the first mesa and the second mesa comprises a JFET region, wherein the JFET region is at least partially vertically aligned with the first doped column.

9. The semiconductor device of claim 1, further comprising a planar gate structure on each of the first mesa and the second mesa.

10. The semiconductor device of claim 1, further comprising a trench gate structure in each of the first mesa and the second mesa.

11. The semiconductor device of claim 1, wherein each of the first mesa and the second mesa comprises a well region, wherein the two second doped columns for each of the first mesa and the second mesa extends from the well region to a drift region.

12. The semiconductor device of claim 1, wherein each of the first mesa and the second mesa have a height in a range of about 1 micron to about 5 microns.

13. The semiconductor device of claim 1, wherein the dielectric comprises silicon dioxide or a silicate glass.

14. The semiconductor device of claim 1, wherein the first dopants comprise n-type dopants and the second dopants comprise p-type dopants, wherein the first doped column is between the two second doped columns.

15. The semiconductor device of claim 1, wherein the first dopants comprise p-type dopants and the second dopants comprise n-type dopants, wherein the first doped column is between the two second doped columns.

16. The semiconductor device of claim 1, wherein the wide bandgap semiconductor structure comprises silicon carbide.

17. The semiconductor device of claim 1, wherein the semiconductor device is a MOSFET or an IGBT.

18. A method of fabricating a semiconductor device, comprising:
providing a wide bandgap semiconductor structure on a substrate;
providing one or more mesas in the wide bandgap semiconductor structure;
implanting dopants at a non-perpendicular implant angle into each of the one or more mesas.

19. The method of claim 18, wherein the non-perpendicular implant angle is in a range of about 15 degrees to about 75 degrees from a vertical axis.

20. A semiconductor device comprising:
a substrate;
a wide bandgap semiconductor structure, the semiconductor structure comprising a drift region and at least one mesa on the drift region;
a first doped column in the mesa, the first doped column comprising dopants of a first conductivity type;
two second doped columns in the mesa, the second doped columns comprising dopants of a second conductivity type;
a gate structure on the mesa;
wherein the first doped column is between the two second doped columns, wherein the first doped column and the two second doped column provide a charge-balanced structure.
